(19) United States
(12) Patent Application Publication
(10) Pub. No.: US 2026/0165123 A1
(43) Pub. Date: Jun. 11, 2026

(54) ELECTRONIC DEVICES AND METHODS OF MANUFACTURING ELECTRONIC DEVICES

(71) Applicant: Amkor Technology Singapore Holding Pte. Ltd.

(72) Inventors: Mike Kelly, Mesa, AZ (US); Quan Pham, Chandler, AZ (US); Chandra Pendyala, Queen Creek, AZ (US); Young Do Kweon, Chandler, AZ (US); Ted Adlam, Payson, AZ (US); Tanner Lovell, Tempe, AZ (US); Mingji Wang, Chandler, AZ (US)

(73) Assignee: Amkor Technology Singapore Holding Pte. Ltd., (omitted)

(21) Appl. No.: 19/412,663

(22) Filed: Dec. 8, 2025

Related U.S. Application Data
(60) Provisional application No. 63/730,329, filed on Dec. 10, 2024.
(60) Provisional application No. 63/858,186, filed on Aug. 5, 2025.

(51) Int. Cl. H10W 40/20; H10W 70/60

(52) U.S. Cl. CPC H10W 40/233; H10W 70/618

(57) ABSTRACT

In one example, an electronic device includes a module comprising electronic components and a first encapsulant disposed around lateral sides of the electronic components. A substrate is coupled to the module. A metallic structure is coupled to a side of the module opposite the substrate, and the metallic structure is coupled to back sides of the electronic components. A thermal interface material is coupled to the metallic structure. A lid is coupled to the thermal interface material. Other examples and related methods are also disclosed herein.

### CROSS REFERENCE TO RELATED APPLICATIONS

This application claims priority to U.S. Provisional Patent Application No. 63/730,329, filed on Dec. 10, 2024 and entitled “ELECTRONIC DEVICES AND METHODS OF MANUFACTURING ELECTRONIC DEVICES,” and to U.S. Provisional Patent Application No. 63/858,186, filed on Aug. 5, 2025 and entitled “ELECTRONIC DEVICES AND METHODS OF MANUFACTURING ELECTRONIC DEVICES,” both of which are incorporated herein by reference for any purpose.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device, in accordance with various examples.

FIGS. 2A-2J show an example method of making an electronic device, in accordance with various examples.

FIGS. 3A-3E show an example method of making an electronic device, in accordance with various examples.

FIG. 4 shows a cross-sectional view of an example electronic device, in accordance with various examples.

FIG. 5A-5B show an example method of making an electronic device, in accordance with various examples.

FIG. 6 shows a cross-sectional view of an example electronic device, in accordance with various examples.

FIG. 7 shows a cross-sectional view of an example electronic device, in accordance with various examples.

FIG. 8 shows a cross-sectional view of an example electronic device, in accordance with various examples.

FIG. 9 shows a cross-sectional view of an example electronic device, in accordance with various examples.

FIG. 10 shows a cross-sectional view of an example electronic device, in accordance with various examples.

FIG. 11 shows a cross-sectional view of an example electronic device, in accordance with various examples.

FIGS. 12A-12I show an example method of making an electronic device, in accordance with various examples.

FIGS. 13A-13F show an example method of making an electronic device, in accordance with various examples.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of the stated features, but do not preclude the presence or addition of one or more other features.

The terms “first,” “second,” etc. may be used herein to describe various elements. These elements are not limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or to describe two elements indirectly coupled by one or more other elements. For example, if element A is coupled to element B, then element A can be contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to a mechanical coupling or an electrical coupling.

### DESCRIPTION

In one example, an electronic device includes a module comprising electronic components and a first encapsulant disposed around lateral sides of the electronic components. A substrate is coupled to the module. A metallic structure is coupled to a side of the module opposite the substrate, and the metallic structure is coupled to back sides of the electronic components. A thermal interface material is coupled to the metallic structure. A lid is coupled to the thermal interface material.

Another example electronic device includes a substrate, a first electronic component coupled to the substrate, and a second electronic component coupled to the substrate adjacent the first electronic component. An encapsulant is disposed over the substrate and around lateral sides of the first electronic component and the second electronic component. A metallic structure is coupled directly to the back side of the first electronic component, a back side of the second electronic component, and an outer side of the encapsulant. The metallic structure is inset from a lateral side of the encapsulant by a pullback distance.

An example method of making an electronic device includes the step of providing a module including electronic components and a first encapsulant disposed around lateral sides of the electronic components. A substrate is provided with the module coupled to an inner side of the substrate. A metallic structure is provided over the module with the metallic structure coupled to outer sides of the electronic components that are exposed from the first encapsulant. The example method includes providing a thermal interface material (TIM) over the metallic structure, and providing a lid over the TIM.

Other examples are included in the present disclosure. Such examples may be found in the figures, in the claims, or in the description of the present disclosure.

Various example electronic devices and related methods can improve mechanical behavior of electronic devices undergoing thermal changes. In some examples, the Coefficient of Thermal Expansion (CTE) of a substrate or of redistribution structures can be dominated by the metals included in the structures. A redistribution layer on one side of the electronic device can have a greater CTE than semiconductor materials and other components in a module or package. CTEs described herein can be given in parts per million change per degree Celsius (ppm/° C.). In some devices, the difference in thermal expansion can result in a bowed shape or cry shape as an electronic device is heated during reflow of device interconnects and then cooled back to room temperature. Changing shape during heating and cooling can result in difficulties joining the electronic device to a substrate.

In various examples, a metallic structure can be provided on the back side of an electronic component. The metallic structure can comprise a metal layer plated on a module or package, for example. The metallic structure can comprise nickel, copper, or gold and can be formed using plating or other electrodeposition processes that result in a metallurgical bond. In some examples, the metallic structure can comprise titanium, vanadium, titanium copper, nickel vanadium, or nickel copper and can be sputtered on in a thin film chamber. A metallic thermal interface material (TIM) can be coupled to the metallic structure, and the metallic TIM can also be coupled to a lid. The CTE of the metallic structure can offset the CTE of the substrate or redistribution structure, which can reduce warpage in response to changing thermal conditions.

In still other examples, electronic devices and related methods can improve thermal performance and reduce manufacturing costs. Direct application of heat spreaders, for example, can eliminate or reduce the application of thermal interface material. Less thermal interface material can mean less void formation and reduced reliance on thermal properties of the thermal interface material. Inset or pullback of heat spreaders from package edges can also be reduced, which can improve thermal performance by increasing the contact area and exposed surface area of the heat spreader.

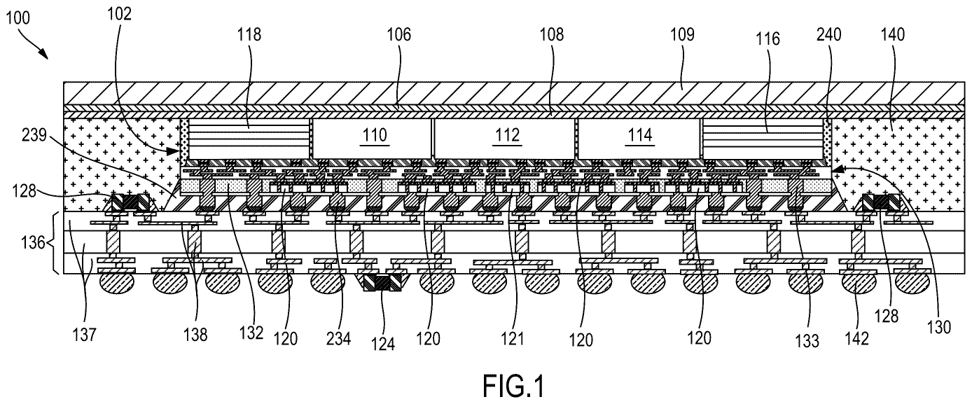

Referring now to FIG. 1, an example electronic device 100 is shown, in accordance with various embodiments. In the example shown in FIG. 1, electronic device 100 comprises module 102, therimal interface material (TIM) 106, metallic structure 108, lid 109, substrate 136, encapsulant 140, and external interconnects 142. Substrate 136 comprises dielectric structure 137 and conductive structure 138. Module 102 can be coupled to substrate 136 (e.g., to conductive structure 138). Encapsulant 140 can be provided around module 102 and over substrate 136. Metallic structure 108 can be on module 102 and encapsulant 140. Lid 109 can be over metallic structure 108 with TIM 106 sandwiched between and thermally coupling metallic structure 108 and lid 109.

In accordance with various examples, module 102 comprises electronic components 110, 112, 114, 116, and 118, redistribution structure 130, one or more bridge die 120, one or more electronic components 122, encapsulant 132, vertical interconnects 133, module interconnects 234, and encapsulant 240. Electronic components 110, 112, 114, 116, and 118 can be coupled to redistribution structure 130. Redistribution structure 130 can comprise dielectric structure 134 and conductive structure 135 formed in one or more interleaved layers. Redistribution structure 130 can electrically couple electronic components 110, 112, 114, 116, and/or 118 to bridge die 120. For example, electronic component 118 can be in electronic communication with electronic component 110 via bridge die 120. Encapsulant 132 can surround bridge die 120, electronic components 121, and vertical interconnects 133. In some examples, electronic component 121 can comprise a deep trench capacitor (DTC) or other passive device. Vertical interconnects 133 can extend through encapsulant 132 and can be coupled to redistribution structure 130 and module interconnects 234. In some examples, a redistribution structure having one or more conductive layers and one or more dielectric layers, similar to redistribution structure 130, can be between vertical interconnects 133 and module interconnects 234. In some examples, bridge die 120 can have conductive through vias (e.g., through silicon vias (TSVs)), which can be coupled to module interconnects 234. Module interconnects 234 can couple module 102 to conductive structure 138 of substrate 136. In various examples, module 102 can include encapsulant 240 disposed around and substantially coplanar with electronic components 110, 112, 114, 116, and 118 and encapsulant 140. As used herein with qualitative terms such as coplanar, substantially can mean within manufacturing tolerances. In some examples, metallic structure 108 can be coupled directly to semiconductor material of electronic components 110, 112, 114, to electronic components 116, 118, to encapsulant 240 and to encapsulant 140.

In some examples, an underfill 239 can be disposed between module 102 and substrate 136. One or more integrated passive devices (IPDs) 128 can be on the upper side of substrate 136 and coupled to conductive structure 138. In some examples, an electronic component 124 (e.g., an IPD or active device) can be coupled to the lower side of substrate 136 and adjacent external interconnects 142.

Coupling module 102 to substrate 136 at normal mass reflow (e.g., isothermal) temperatures can cause module 102 and substrate 136 to form a mechanically bonded unit that is both strong (e.g., has a high modulus) and is prone to crying as the CTE of substrate 136 is higher than the CTE of module 102, in particular higher than the CTE of the electronic component 110-118 at the upper side of the module 102 opposite substrate 136. In some examples, when both the module 102 and substrate 136 cool at the same time (isothermally), the substrate 136 can shrink more and/or at a faster rate than the module 102, due to the difference in CTE. Uneven shrinkage or expansion can create a cry shape. Metallic structure 108 can increase the CTE of module 102 to limit uneven shrinkage and/or reduce warpage of electronic device 100.

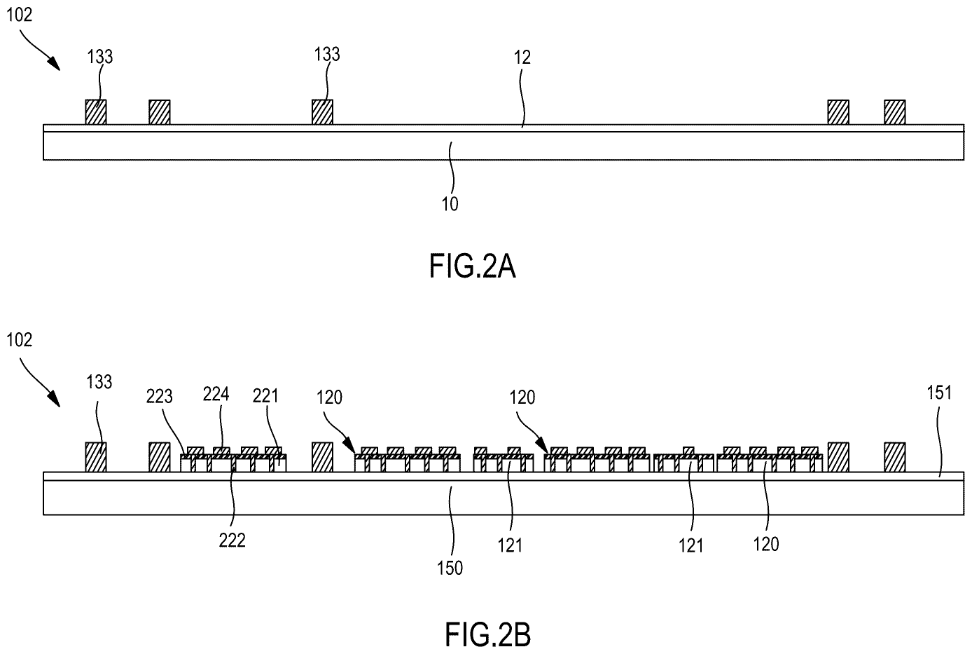

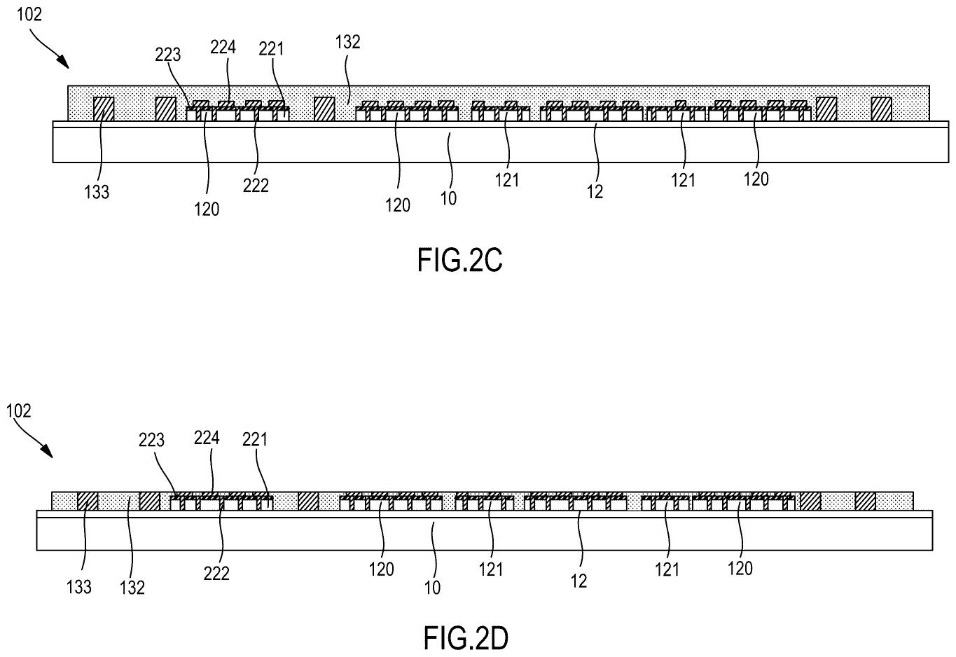

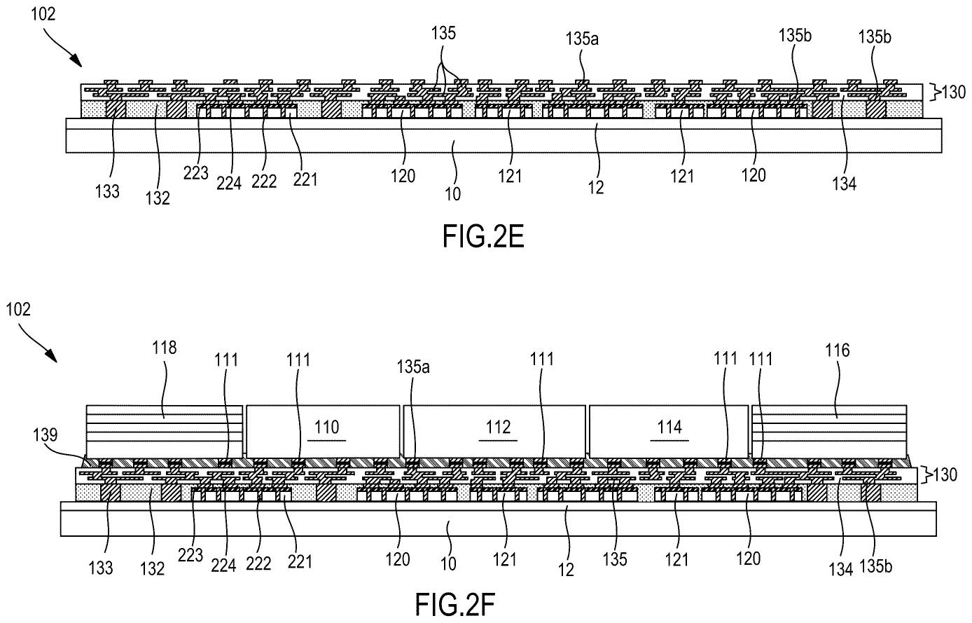

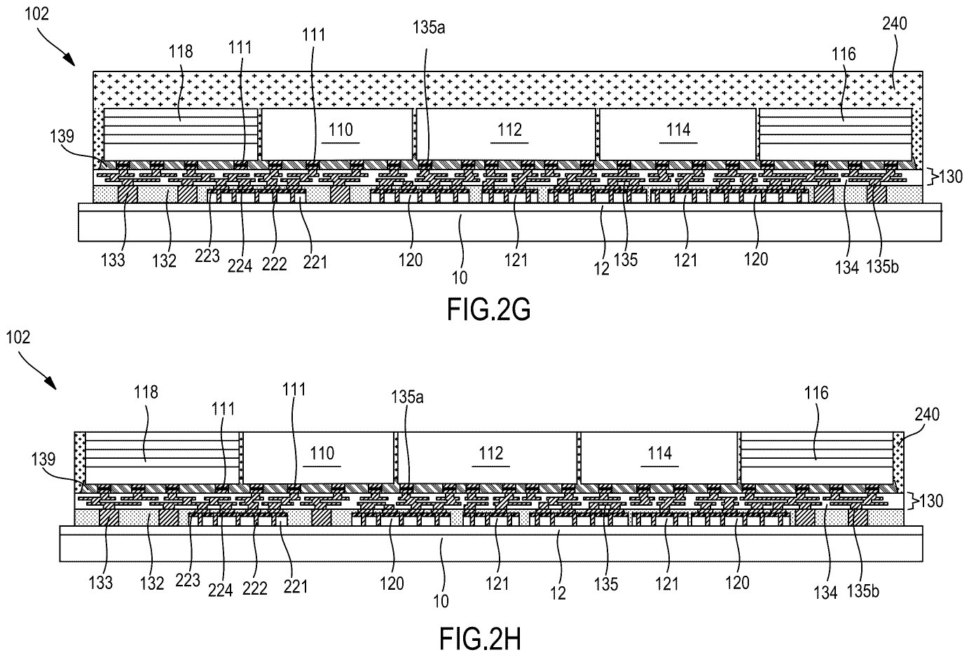

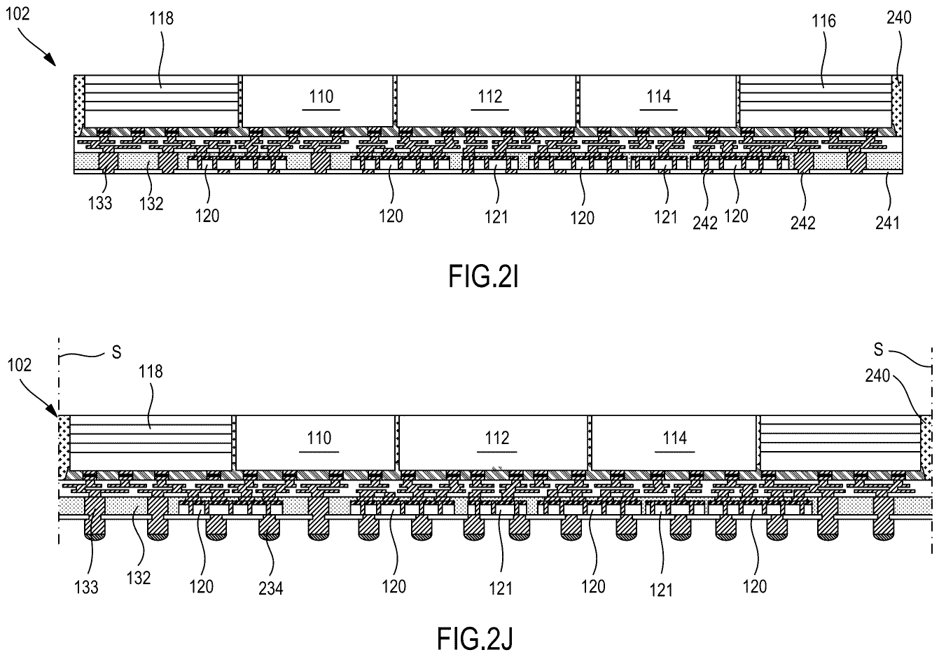

FIGS. 2A through 2J show an example method of making module 102 of electronic device 100 using cross-sectional views. The various steps in the example of FIGS. 2A through 2J can be performed in different orders, omitted, or along with additional steps or with variations suitable to make the various example electronic devices disclosed herein or other related examples.

FIG. 2A shows module 102 at an early stage of manufacture. In the example of FIG. 2A, multiple vertical interconnects 133 can be provided on a top side of carrier 10. In some examples, carrier 10 can include a temporary bond layer 12, which can be in contact with lower ends of vertical interconnects 133.

In accordance with various examples, vertical interconnects 133 can be made of conductive material such as, for example, copper, gold, silver, palladium, or nickel. Vertical interconnects 150 can be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD), or ball drop. In some examples, a seed layer can be formed over temporary bond layer 12 on the top side of carrier 10, and then a mask pattern can be provided on a top side of the seed layer. Vertical interconnects 133 can be formed by plating over exposed portions of the seed layer. After vertical interconnects 133 are provided, the mask pattern(s) and portions of seed layer not covered by vertical interconnects 133 can be removed.

Vertical interconnects 133 can be provided in rows and/or columns over carrier 10. In some examples, the height (i.e., thickness) of vertical interconnects 133 can range from approximately 800 μm to approximately 2000 μm. Vertical interconnects 133 can include or be referred to as vertical conductive structures such as pillars, posts, through mold vias (TMVs), copper core solder balls (CCBs), or solder balls, or copper cube columns (CCCs). In accordance with various examples, CCCs can include a plurality of vertical conductive structures (e.g., columns, pillars, posts, etc.) disposed in an insulating body, such as mold material (e.g., an epoxy mold compound, resin, organic polymer with inorganic filler, etc.).

Carrier 10 can include a substantially planar top side. In some examples, carrier 10 can include or be referred to as a plate, a board, a wafer, a panel, or a support structure. For example, carrier 10 can be provided as a round wafer or square or rectangular panel. In some examples, the width of the first carrier 10 can range from approximately 100 millimeters to approximately 650 mm. Carrier 10 can serve to integrally handle multiple components in the process of providing module(s) 102. Temporary bond layer 12 can comprise or be referred to as a temporary bonding film, a temporary bonding tape, or a temporary adhesive coating. For example, temporary bond layer 12 can comprise a heat release tape (or film), an optical release tape (or film), a chemical release tape (or film), or a laser release tape (or film), wherein the adhesive strength of temporary bond layer 12 is weakened or removed by heat, light, chemical reaction, or laser energy, respectively. Temporary bond layer 12 can facilitate separation of modules 102 from carrier 10 at a later stage of manufacture. In some examples, physical force can be used solely or in addition to heat, light, chemical reaction, and/or laser energy to separate modules 102 from carrier 10.

FIG. 2B shows module 102 at later stage of manufacture. In the example of FIG. 2B, In the example shown in FIG. 2B, bridge die 120 and electronic component(s) 121 can be provided on temporary bond layer 12 over the top side of carrier 10. In some examples, the bridge die 120 and electronic component(s) 121 can be picked up by pick-and-place equipment and placed on the top side of carrier 10. In some examples, the overall thickness of bridge die 120 can range from approximately 10 μm to approximately 800 μm, and the area of bridge die 120 can range from approximately 0.5 mm×0.5 mm to approximately 100 mm×100 mm.

In accordance with various examples, each of the one or more bridge die 120 can include bridge body 221, bridge through-interconnects 222, bridge signal distribution structure 223, and bridge upper interconnects 224. Bridge body 221 can comprise a semiconductor material (e.g., silicon, gallium arsenide (GaAs), indium phosphide (InP), etc.) or mold material that provides a bridge die top side, a bridge die bottom side, and bridge die lateral sides between the bridge die top side, and the bridge die bottom side. Bridge through-interconnects 222 pass vertically through bridge body 221. In particular, an upper end of each bridge through-interconnect 222 can be exposed at the top side of bridge body 221. In some examples, the upper end of each bridge through-interconnect 222 can be coplanar with the top side of bridge body 221. Similarly, a lower end of each bridge through-interconnect 222 can be exposed at the bottom side of bridge body 221. In some examples, the lower end of each bridge through-interconnect 222 can be coplanar with the bottom side of bridge body 221.

In some examples, the bottom side of bridge die 120 can comprise one or more bridge lower dielectric layers. In particular, bridge die 120 can include a silicon nitride (SiN) layer that covers the bottom side of the bridge die 120. Further, bridge die 120 can include a polyimide (PI) layer that covers the bottom side of the bridge die 120 and/or the SiN layer. In some examples, the lower end of each bridge through-interconnect 222 can be coplanar with the bottom side of the lowermost layer of the one or more bridge lower dielectric layers (e.g., the SiN layer or PI layer).

In some examples, each bridge through-interconnect 222 can have a width or diameter ranging from approximately 0.5 μm to approximately 200 μm. Moreover, the bridge through-interconnects 222 can be arranged with a pitch (i.e., spacing between adjacent bridge through-interconnects 222) ranging from approximately 0.5 μm to approximately 200 μm.

Bridge signal distribution structure 223 can be provided over, can be coupled to, and/or can cover the top side of bridge body 221. Further, bridge signal distribution structure 223 can be provided over, can be coupled to, and/or can cover the upper end of each bridge through-interconnect 222. In accordance with various examples, bridge signal distribution structure 223 can include a bridge dielectric structure and a bridge conductive structure. In some examples, the bridge signal distribution structure 135 can be formed during a back-end-of-line (BEOL) process.

The bridge dielectric structure can include one or more dielectric layers made of a dielectric or insulating material interleaved between conductive layers of the bridge conductive structure. In some examples, the bridge dielectric structure can include one or more layers of inorganic dielectric material such as SiO2, SiCN, Si3N4. In some examples, the bridge dielectric structure can include one or more layers of organic dielectric material such as polyimide (PI), polymer, benzocyclobutene (BCB), polybenzoxazole (PBO), bismaleimide triazine (BT), Ajinomoto Buildup Film (ABF) or resin. The bridge dielectric structure can be provided by spin coating, spray coating, dip coating, rod coating, printing, oxidation, PVD, CVD, ALD, LPCVD, PECVD, and/or any other process known to one of ordinary skill in the art. In some examples, the thickness of bridge dielectric structure can range from approximately 0.5 μm to approximately 50 μm. In various examples, the thickness of bridge signal distribution dielectric structure can refer to individual layers of bridge dielectric structure.

The bridge conductive structure can include one or more conductive layers defining signal distribution elements (e.g., traces, vias, pads, conductive paths, and/or UBMs) that are interleaved with dielectric layers of bridge dielectric structure. The one or more conductive layers of the bridge conductive structure can include or be referred to as traces, pads, vias, conductive paths, wire patterns, circuit patterns, redistribution layers (RDLs), and/or UBM. In some examples, the bridge conductive structure can include copper, aluminum, iron, nickel, gold, silver, palladium, titanium, and/or tin. The bridge conductive structure can be provided by electrolytic plating, electroless plating, sputtering, deposition such as PVD, CVD, MOCVD, ALD, LPCVD, or PECVD. The bridge conductive structure can distribute electrical signals in a vertical direction and a lateral direction through the bridge signal distribution structure 223. In some examples, each conductive layer of the bridge conductive structure can have a thickness range from approximately 0.5 μm to approximately 20 μm. In some examples, the line width and the line spacing of the bridge conductive structure (i.e., the lateral width of individual traces of the bridge conductive structure and the lateral distance between adjacent traces of the bridge conductive structure) can be approximately 0.5 μm to approximately 20 μm, approximately 1.0 μm to approximately 10 μm or approximately 2.0 μm to approximately 5.0 μm.

In some examples, the bridge conductive structure can provide conductive paths having a narrower width and/or a finer pitch than conductive paths provided by the conductive structure of redistribution structure 130 (FIG. 1). In this manner, bridge signal distribution structure 223 can provide denser routing of signals than redistribution structure 130. By providing communication between electronic components, bridge signal distribution structure 223 can also reduce the number of layers in redistribution structure 130, which can simplify manufacturing, decrease costs, and improve yields.

In accordance with various examples, bridge interconnects 224 can be coupled to upper terminals of the bridge conductive structure. Bridge upper interconnects 224 can include or be referred to as pads, bumps, pillars, conductive posts, or solder balls. Bridge upper interconnects 224 can include conductive material such as aluminum, copper, an aluminum alloy, a copper alloy, solder, etc.

The bridge conductive structure can be coupled to bridge through-interconnects 222 and to bridge upper interconnects 224. The bridge conductive structure can electrically couple one or more of the bridge upper interconnects 224 to one or more of the bridge through-interconnects 222. In accordance with various examples, at least some of the bridge upper interconnects 224 are not electrically coupled to the bridge through-interconnects 222 and instead provide electrical connection between a first one of electronic components 110, 112, 114, 116, 118 (FIG. 1) and a second one of electronic components 110, 112, 114, 116, 118.

In some examples, one or more electronic component 121 can also be provided over carrier 10 and temporary bonding layer. In some examples, electronic component 121 can comprise a passive device (e.g., a capacitor, resistor, inductor, etc.). In some examples, one or more of the electronic component(s) 121 includes a deep trench capacitor (DTC). In some examples, one or more of electronic component(s) 121 can comprise a dummy die, used for structural support and/or CTE balancing and which does not include an electronical interconnection to any other components within module 102. In some examples, electronic component 121 can comprise an active component (e.g., semiconductor die having an active (e.g., transistor) region or other integrated circuits).

Referring now to FIG. 2C a cross-sectional view of module 102 at a later stage of manufacture is shown. In the example shown in FIG. 2C, encapsulant 132 can be provided to cover carrier 10, bridge die 120, electronic components 121, and vertical interconnects 133. Encapsulant 132 can contact temporary bond layer 12 on the top side of carrier 10, the lateral sides or sidewalls of bridge die 120 and electronic component(s) 121, the top sides of bridge die 120 and electronic component(s) 121, the lateral sides or sidewalls of vertical interconnects 133, and the upper ends of vertical interconnects 133. In some examples, encapsulant 132 can be provided by compression molding, transfer molding, liquid body molding, vacuum lamination, paste printing, film-assisted molding, or any other suitable deposition process. Encapsulant 132 can comprise or be referred to as a package body, an encapsulating structure, an insulator, a mold, an epoxy molding compound (EMC), a resin, a filler-reinforced polymer, a B-stage compressed film, gel, etc.

Referring now to FIG. 2D a cross-sectional view of module 102 at a later stage of manufacture is shown. In some examples, after encapsulant 132 is provided, an upper portion of encapsulant 132 can be removed to expose the upper ends of bridge upper interconnects 224 and the upper ends of vertical interconnects 133 as shown at FIG. 2D. For example, the upper portion of encapsulant 132 can be removed by grinding and/or chemical etching of the top side of encapsulant 132. Encapsulant 132 can protect bridge die 120, electronic components 121, and vertical interconnects 133 from external elements.

FIG. 2E shows a cross-sectional view of module 102 at a later stage of manufacture. In the example shown in FIG. 2E, redistribution structure 130 can be provided such that redistribution structure 130 is positioned over, can cover, and/or can be coupled to encapsulant 132, bridge die 120, electronic components 121, and vertical interconnects 133.

Redistribution structure 130 can include dielectric structure 134 and conductive structure 135. Conductive structure 135 can include upper terminals 135a and lower terminals 135b. In particular, providing dielectric structure 134 can include spin coating, spray coating, dip coating, rod coating, PVD, CVD, or any other suitable methods for forming an electrically insulating material such as polyimide (PI), benzocyclobutene (BCB), polybenzoxazole (PBO), resin, or Ajinomoto buildup film (ABF). Such formation can provide dielectric structure 134 such that dielectric structure 134 is over, cover, and/or is coupled to a top side of encapsulant 132, an upper end of each bridge upper interconnect 224, an upper side of electronic components 121, and an upper end of each vertical interconnect 133. In some examples, after the lowermost (or first) layer of dielectric structure 134 is provided, openings exposing an upper end of each bridge upper interconnect 224 and an upper end of each vertical interconnect 133 and openings exposing interconnects of electronic components 121 can be provided. For example, after forming a mask pattern on the top side of the lowermost layer of dielectric structure 134, openings can be formed by removing exposed portions of the dielectric layer through etching. Portions of conductive structure 135 (e.g., lower terminals 135b) can then be provided in the openings, such that the portions of conductive structure 135 can couple to and/or can contact exposed upper ends of bridge upper interconnects 224 and exposed upper ends of vertical interconnects 133, and expose interconnects of electronic components 121.

Formation of redistribution structure 130 can include interleaving layers of conductive structure 135 with layers of dielectric structure 134. In accordance with various examples, conductive structure 135 can be provided by electrolytic plating, electroless plating, sputtering, PVD, CVD, MOCVD, ALD, LPCVD, PECVD, or any other suitably process for deposing metals such as copper, gold, silver, aluminum, nickel, palladium, titanium, tungsten, etc. In some examples, conductive structure 135 can be provided by plating. For example, after a metal seed layer is provided to cover exposed upper ends of the bridge upper interconnects 224, exposed upper ends of vertical interconnects 133, exposed interconnects of electronic components 121, and a top side of a dielectric layer of dielectric structure 134, a mask pattern can be provided to cover the top side of the metal seed layer. A conductive layer of conductive structure 135 can then be provided through plating using exposed portions of the metal seed layer as a seed. After the conductive layer is formed, the mask pattern can be removed.

Conductive structure 135 can provide electrical signal paths (e.g., vertical paths and horizontal paths) through dielectric structure 134. Conductive structure 135 can be exposed at an inner side of redistribution structure 130 and can comprise inner terminals 135a along the inner side of redistribution structure 130. Conductive structure 135 can also be exposed at an outer side of redistribution structure 130 and can comprise outer terminals 135b along the outer side of redistribution structure 130. In some examples, outer terminals 135b can comprise or be referred to as pads, lands, studs, or UBM. In some examples, inner terminals 135a can comprise or be referred to as pads, lands, vias, or UBM. Outer terminals 135b can be coupled to and/or can contact bridge upper interconnects 224, upper ends of vertical interconnects 133, and interconnects of electronic components 121. Layers and elements of conductive structure 135 can electrically couple inner terminals 135a with outer terminals 135b.

In some examples, redistribution structure 130 can comprise or be referred to a redistribution layer (“RDL”) or build-up substrate. RDL substrates can comprise one or more conductive redistribution layers, for examples layers of conductive structures 135, and one or more dielectric layers, for example layers of dielectric structure 134, that (a) can be formed layer by layer over an electronic device to which the RDL substrate is to be coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process that can include one or more dielectric layers alternatingly formed with one or more conductive layers that define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. Thus, the dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, which could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples, the dielectric materials of the RDL substrates can comprise one or more inorganic dielectric layers. Some examples of inorganic dielectric layers can comprise silicon nitride (Si3N4), silicon oxide (SiO2), or silicon oxynitride (SiON). The inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. RDL substrates can omit the permanent core or carrier structure generally associated with preformed, laminate substrates, as described below. Other substrates and signal distribution structures of this disclosure such as the bridge signal distribution structures 223, and/or substrate 136 (FIG. 1) can include RDL substrates.

In some examples, redistribution structure 130 can comprise or be referred to as a pre-formed or laminate substrate. Pre-formed substrates can be manufactured prior to attachment to an electronic component and can include dielectric layers between respective conductive layers. The conductive layers can include copper and can be formed using an electroplating process. The dielectric layers can be relatively thicker non-photo-definable layers and can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can include a prepreg material or Ajinomoto Buildup Film (ABF). The pre-formed substrate can include a permanent core structure or carrier such as, for example, a dielectric material comprising bismaleimide triazine (BT) or FR4. In some examples, the permanent core structure can be glass. The dielectric and conductive layers can be formed on the permanent core structure. In other examples, the pre-formed substrate can be a coreless substrate and omits the permanent core structure, and the dielectric and conductive layers can be formed on a sacrificial carrier that is removed after formation of the dielectric and conductive layers and before attachment to the electronic component. The pre-formed substrate can be referred to as a printed circuit board (PCB) or a laminate substrate. Such pre-formed substrates can be formed through a semi-additive or modified-semi-additive process. Other substrates and signal distribution structures of this disclosure can include a pre-formed substrate.

FIG. 2F shows a cross-sectional view of module 102 at a later stage of manufacture. In the example shown in FIG. 2F, electronic components 110, 112, 114, 116, and 118 can be provided over redistribution structure 130. Each of electronic components 110, 112, 114, 116, and 118 can include component interconnects 111 (e.g., bumps, Cu post, pillar, Cu post with solder caps, etc.).

Pick-and-place equipment can pick up electronic components 110, 112, 114, 116, and 118 and place electronic components 110, 112, 114, 116, and 118 on the top side of redistribution structure 130. Component interconnects 111 of each electronic component 110, 112, 114, 116, and 118 can be positioned on a respective upper terminal 135a of conductive structure 135. Subsequently, component interconnects 111 can be bonded with their respective upper terminals 135a through a reflow process, a thermal compression process, a hybrid bonding process, or a laser assisted bonding process.

In accordance with various examples, electronic components 110, 112, 114, 116, and 118 can each comprise or be referred to as a die, chip, semiconductor package (e.g., multiple interconnected and/or stacked die and/or one or more die coupled to an interposer substrate), passive component, antenna patch, or power device. In some examples, one or more of electronic components 110, 112, 114, 116, and 118 can comprise a digital signal processor (DSP), network processor, power management unit, audio processor, radio-frequency (RF) circuit, wireless baseband processor, system-on-chip (SoC) processor, sensor, or application-specific integrated circuit (ASIC). In some examples, one or more of electronic components 110, 112, 114, 116, and 118 can be configured to perform calculation and control processing, store data, or remove noise from electrical signals.

In some examples, at least one of electronic component 116 and/or electronic component 118 can comprise a semiconductor package. For example, electronic component 116 and/or electronic component 118 can include multiple interconnected and/or stacked die and/or one or more die coupled to an interposer substrate. In some examples, electronic component 116 and/or electronic component 118 can comprise memory die or memory package(s) and at least one of electronic component 110, electronic component 112 and/or electronic component 114 comprises a logic die (e.g., a central processing unit (CPU), graphics processing unit (GPU), or application specific integrated circuit (ASIC), etc.) or system on chip (SoC) die. In some examples, the memory die or package can comprise a high bandwidth memory (HBM) device. In some examples, the HBM device can include a controller die having a stack of memory die located thereon. The controller die and memory stack can be encapsulated. In some examples, a first bridge die 120 electrically couples electronic component 110 to electronic component 118, and a second bridge die 120 electrically couples electronic component 114 to electronic component 116. In some examples, one or more bridge die 120 can electrically couple electronic component 110, electronic component 112, and/or electronic component 114.

As further shown in the example of FIG. 2F, underfill 139 can be provided between redistribution structure 130 and electronic components 110, 112, 114, 116, and 118. In some examples, underfill 139 can span the lateral space between electronic components 110, 112, 114, 116, and 118. Underfill 139 can comprise an electrically insulating material. In some examples, underfill 139 can be devoice of inorganic fillers. In some examples, underfill 139 can comprise or be referred to as a capillary underfill (CUF), a non-conductive paste (NCP), a non-conductive film (NCF), an anisotropic conductive film (ACF), or an anisotropic conductive paste (ACP). In some examples, the underfill process of FIG. 2F can be omitted. In such examples, encapsulant 240, as provided in FIG. 2G, can underfill the space between redistribution structure 130 and electronic components 110, 112, 114, 116, and 118, effectively replacing the underfill 139. In such examples, encapsulant 240 can comprise or be referred to as molded underfill (MUF).

FIG. 2G shows a cross-sectional view of module 102 at a later stage of manufacture. In the example shown in FIG. 2G, encapsulant 240 can be provided to over electronic components 110, 112, 114, 116, and 118 and redistribution structure 130. Encapsulant 240 can contact a top side and sidewalls of electronic components 110, 112, 114, 116, and 118, a top side of redistribution structure 130, and/or a sidewall of underfill 139. In some examples, elements, features, materials, or manufacturing methods of encapsulant 240 can be similar to or the same as those of encapsulant 132. Encapsulant 240 can protect electronic components 110, 112, 114, 116, and 118 from external elements.

FIG. 2H shows a cross-sectional view of module 102 at a later stage of manufacture. In some examples, after encapsulant 240 is provided, an upper portion of encapsulant 240 can be removed to thin module 102 and/or to expose the upper (or back) side of one or more of electronic component 110, 112, 114, 116, and/or 118, as shown at FIG. 2H. For example, the upper portion of encapsulant 240 can be removed by grinding and/or chemical etching of the top side of encapsulant 240. The top side of encapsulant 240 can be coplanar with the top side of one or more of electronic component 110, 112, 114, 116, and/or 118.

FIG. 2I shows a cross-sectional view of module 102 at a later stage of manufacture. In the example shown in FIG. 2I, carrier 10 can be removed from the bottom side of bridge die 120, the bottom side of encapsulant 132, and the lower ends of vertical interconnects 133.

As a result of carrier 10 being removed, the bottom side of encapsulant 132, the lower ends of vertical interconnects 133, the bottom side of bridge die 120, and the bottom side of electronic components 121 can be exposed. In some examples, the lower ends of bridge through-interconnects 222 can be exposed after removal of carrier 10. In some examples, a die attach film (DAF) can be on the bottom side of electronic components 121 and/or on the bottom side of bridge die 120, and removal of carrier 10 can expose the DAF.

As further shown at FIG. 2I, a lower passivation structure 241 and lower conductive structure 242 can be provided on the bottom side of bridge die 120, the bottom side of encapsulant 132, and the lower ends of vertical interconnects 133. In some examples, lower passivation 241 can comprise a dielectric material such as polymer, BT, PI, BCB, PBO, etc. Lower conductive structure 242 can include one or more layers of copper, aluminum, iron, nickel, gold, silver, palladium, titanium, tin, or other suitable electrically conductive material. In some examples, lower conductive structure 242 can comprise or be referred to as a UBM. Lower conductive structure 242 can be coupled to and/or can contact the lower ends of bridge through-interconnects 222 and the lower ends of vertical interconnects 133. In some examples, lower passivation structure 241 and lower conductive structure 242 can be provided as a multilayer interleaved structures similar to dielectric structure 134 and conductive structure 135 of redistribution structure 130.

FIG. 2J shows a cross-sectional view of module 102 at a later stage of manufacture. In the example shown in FIG. 2J, module interconnects 234 can be provided on bottom side of the lower conductive structure 242. In particular, module interconnects 234 can be provided such module interconnects 234 are coupled to bridge through-interconnects 222 and vertical interconnects 133 via lower conductive structure 242. In some examples, module interconnects 234 can include tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, module interconnects 234 can be provided through a reflow process after forming a conductive material including solder on lower conductive structure 242 through a ball drop method. Module interconnects 234 can include or be referred to as conductive balls such as solder balls, conductive pillars such as copper pillars, or conductive posts having solder caps provided on copper pillars. In some examples, module interconnects 234 can be referred to as external input/output terminals of module 102.

In the example shown in FIG. 2J, singulation can also be performed. In some examples, after providing module interconnects 234 a singulation process can be performed. In accordance with various examples, singulation can be performed by cutting through saw streets, for example indicated by lines S, disposed around a perimeter of modules 102, thereby separating individual modules 102 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through encapsulant 240, redistribution structure 130, encapsulant 132, and/or lower passivation 241. After singulation, encapsulant 240, redistribution structure 130, encapsulant 132, and/or lower passivation 241 can be coplanar with one another.

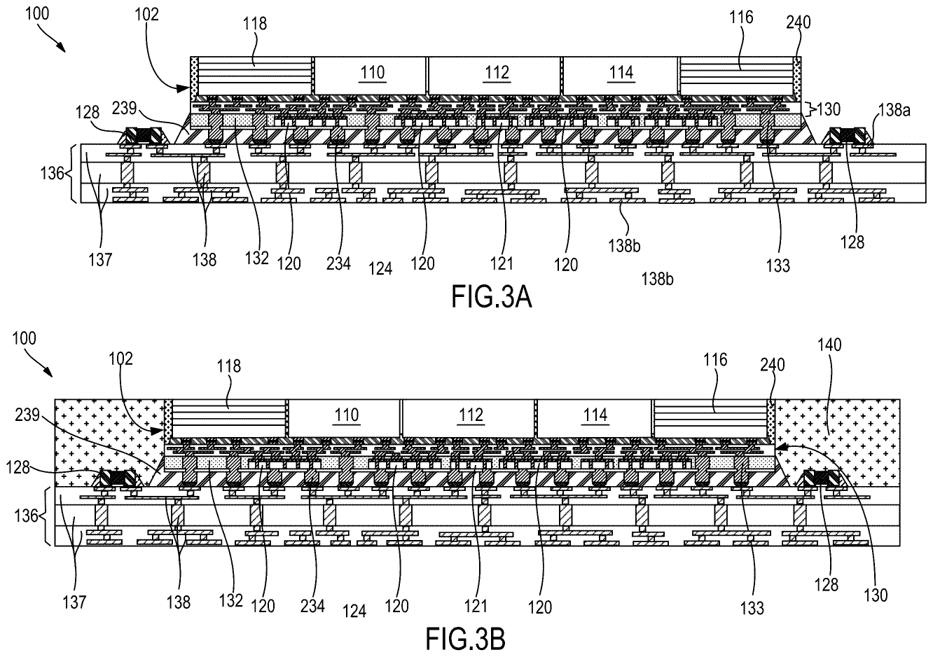

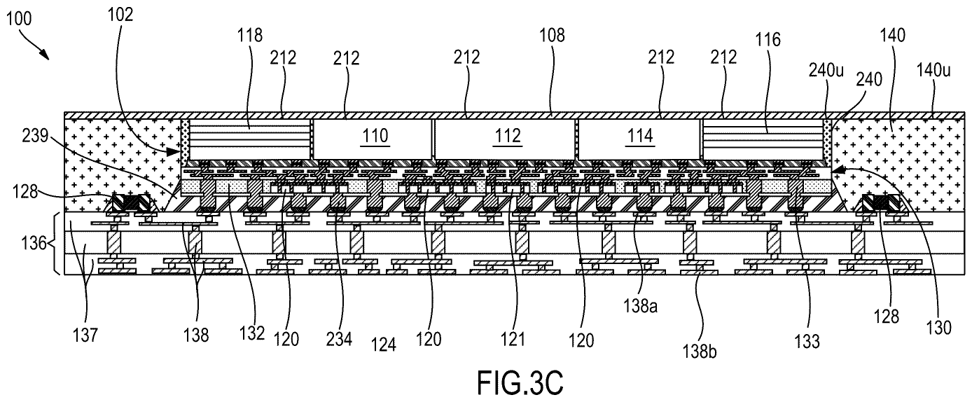

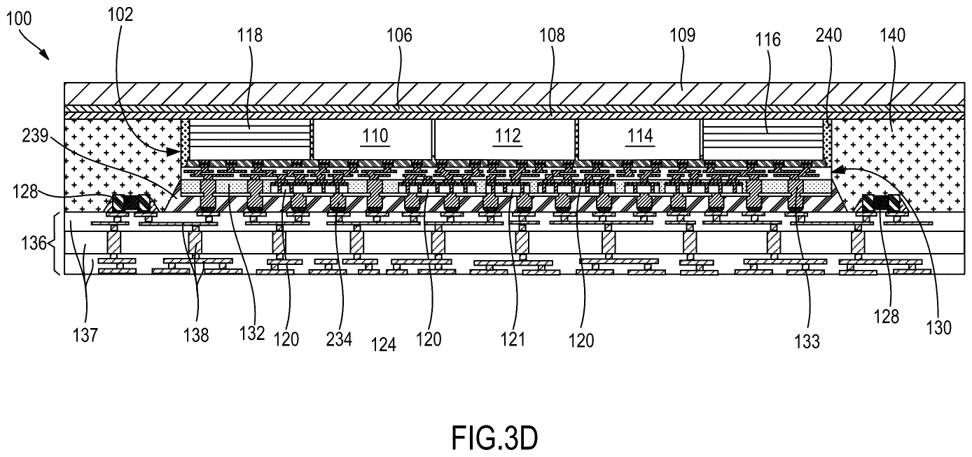

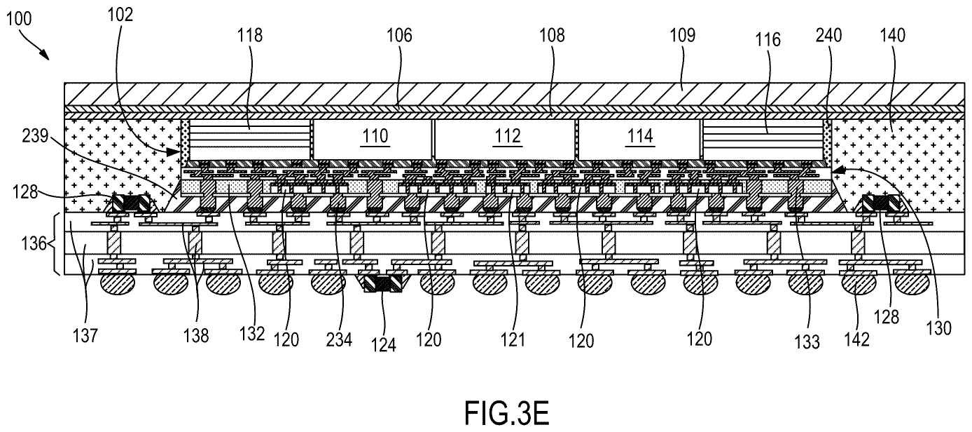

FIGS. 3A through 3E show an example method of making electronic device 100 of FIG. 1 using cross-sectional views. The various steps in the example of FIGS. 3A through 3E can be performed in different orders, omitted, or along with additional steps or with variations suitable to make the various example electronic devices disclosed herein or other related examples.

FIG. 3A shows electronic device 100 at an early stage of manufacture. In the example of FIG. 2A, module 102 can be provided over substrate 136. Module 102 can be coupled to substrate 136 by module interconnects 234. Module interconnects 234 can be coupled to inner terminals 138a of conductive structure 138 substrate 136.

In some embodiments, substrate 136 can be provided as part of a strip, wafer, or panel of substrates 136. The substrate strip, wafer, or panel can include multiple adjacent, connected substrates 136 separated by saw streets. In some embodiments, substrate 136 can be provided as a discrete, singulated substrate, for example coupled to a carrier or substrate boat.

In accordance with various examples, substrate 136 comprises dielectric structure 137 and conductive structure 138. In some examples, dielectric structure 137 can comprise or be referred to as one or more stacked dielectric layers. For instance, the one or more dielectric layers can comprise one or more core layers, polymer layers, pre-preg layers, solder mask layers, etc. stacked on each other. One or more layers or elements of conductive structure 138 can be interleaved with elements or layers of the dielectric structure 137. In some examples, the dielectric structure can comprise polymer, bismaleimide triazine (BT), polyimide (PI), benzocyclobutene (BCB), polybenzoxazole (PBO), Ajinomoto Buildup Film (ABF), resin, mold compound, ceramic, glass, silicon, or copper clad laminate, flame retardant material (e.g., FR4 comprising laminated layers of copper foil and glass fiber fabric). In some examples, substrate 136 can have a glass core. Dielectric structure 137 can maintain the shape of substrate 136 and can structurally support the conductive structure 138.

Conductive structure 138 can comprise or be referred to as one or more conductive layers defining signal distribution elements, traces, vias, pads, conductive patterns, conductive paths, wiring patterns, circuit patterns, or under bump metallization (UBM). In some examples, conductive structure 138 can comprise one or more layers of copper (Cu), aluminum (Al), tin (Sn), titanium (Ti), titanium tungsten (TiW), gold (Au), silver (Ag), nickel (Ni), palladium (Pd), or combinations or alloys thereof. The layers and elements of conductive structure 138 can be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or any other suitable metal deposition process. Conductive structure 138 can provide electrical signal paths (e.g., vertical paths and horizontal paths) through dielectric structure 137.

Conductive structure 138 can be exposed at an inner side of substrate 136 and can comprise inner terminals 138a along the inner side. Conductive structure 138 can also be exposed at an outer side of substrate 136 and can comprise outer terminals 138b along the outer side. In some examples, the inner terminals and outer terminals can comprise or be referred to as pads, lands, studs, or UBM. Layers and elements of conductive structure 138 can electrically couple inner terminals 138a with outer terminals 138b.

In some examples, substrate 136 can be a pre-formed or laminate substrate, as previously described. In some examples, substrate 136 can be an RDL or build-up substrate as previously described.

In some examples, one or more electronic component(s) 128 can be coupled to substrate 136 around a periphery or perimeter of module 102. In some examples, electronic component 128 can be a passive device. In some examples, electronic component 128 can be an active component.

In accordance with various examples, underfill 239 can be provided between module 102 and substrate 136. Underfill 239 can surround and/or contact module interconnects 234. The elements, features, materials, and/or manufacturing methods of underfill 239 can be similar to or the same as underfill 139, as previously described.

FIG. 3B shows electronic device 100 at a later stage of manufacture. In the example of FIG. 3B, encapsulant 140 can be provided over module 102 and substrate 136.

In accordance with various embodiments, encapsulant 140 can cover module 102, electronic components 128 and the upper side of substrate 136. In some examples (e.g., when module 102 is coupled to a discrete, singulated substrate 136) encapsulant 140 can extend over the lateral side of substrate 136. Encapsulant 140 can comprise or be referred to as a package body, an encapsulating structure, an insulator, a mold, an epoxy molding compound (EMC), a resin, a filler-reinforced polymer, a B-stage compressed film, gel, or the like. Encapsulant 140 can be provided by transfer molding, compression molding, liquid encapsulant molding, vacuum lamination, paste printing, film assisted molding, or any other suitable process. In some examples, encapsulant 140 can completely cover the top side of module 102 initially such that electronic components 110, 112, 114, 116, 118, are covered by encapsulant 140. Encapsulant 140 can protect electronic components 110-118 from the external environment. In some examples, encapsulant 140 can be between substrate 136 and a module 102. For example, encapsulant 140 can comprise a molded underfill (MUF) and underfill 239 can be omitted. In accordance with various examples, after encapsulant 140 is provided, an upper portion of encapsulant 140 can be removed to expose the upper sides of one or more of electronic components 110, 112, 114, 116, 118. For example, the upper portion of encapsulant 140 can be removed by grinding and/or chemical etching of the top side of encapsulant 140. The upper side of encapsulant 140 can be coplanar with the upper sides of electronic components 110, 112, 114, 116, 118 and encapsulant 240.

With reference to FIG. 3C, electronic device 100 is shown at a later stage of manufacture. In the example of FIG. 3C, metallic structure 108 can be provided over encapsulant 140 and module 102. Metallic structure 108 can comprise metals, alloys, or compounds such as, for example, copper, aluminum, aluminum silicon carbide, or other suitable materials having desired CTE properties. The material used for metallic structure 108 can be selected based on the CTE properties of substrate 136. Metallic structure 108 can also be selected based on thermal conductivity in electronic devices 100, such that the material of metallic structure 108 can be selected based on thermal dissipation needs of electronic component(s) 110, 112, 114, 116, and/or 118.

In some examples, metallic structure 108 can be provided to cover exposed sides of electronic components 110-118 and upper side 240u of encapsulant 240 and upper side 140u of encapsulant 140. Metallic structure 108 can be in contact with an outer side 212 of one or more of electronic components 110-118 and upper side 140u of encapsulant 140 and the upper side 240u of encapsulant 240. In some examples, the sidewalls of metallic structure 108 can be substantially coplanar with the sidewalls of encapsulant 140. In some examples, the thickness of metallic structure 108 can range from approximately 3.0 μm to approximately 35 μm, approximately 5.0 μm to approximately 25 μm, or approximately 5.0 μm to approximately 15 μm, or approximately 10.0 μm to approximately 15 μm.

In some examples, metallic structure 108 can comprise a multi-layer metal stack. For example, metal layer can comprise an adhesion layer (e.g., Ti or TiW), a barrier layer (e.g., Ni or NiV) applied on the adhesion layer, a stiffener layer (e.g., Cu) applied on the barrier layer, and oxidation prevention or wetting layer (Ni, NiV, SUS, Au or Ag) applied on the stiffener layer. In some examples, the adhesion layer (e.g., Ti or TiW) and barrier layer (e.g., Ni or NiV) can be provided by sputtering and the barrier layer can be applied by plating. For example, after providing the adhesion and barrier layers, a Cu seed layer can be provided over the barrier layer, Cu can then be plated on the seed layer. In some examples, the thickness of the stiffener layer (e.g., the plated Cu) can be larger than the thickness of the adhesion and barrier layers. For example, the adhesion and barrier layers can each have a thickness of approximately 3 μm or less, or 1 μm or less, or 0.5 μm or less. The stiffener layer can have a thickness of 3 μm or greater, 5 μm or greater, or 10 μm or greater, and/or between 2 μm and 35 μm, between 5 μm and 25 μm, or between 10 μm and 15 μm. The thickness of the stiffener layer can be determined based on the desired CTE and warpage tendencies of the package. For example, a thinner stiffener layer can be used for materials having a greater CTE (e.g., CTE greater than 20 or greater than 25), while a thicker stiffener layer can be used for materials having a lower CTE (e.g., CTE less than 20 or less than 17). The oxidation prevention or wetting layer (Ni, NiV, SUS, Au, or Ag) can be applied over the plated stiffener layer by sputtering, plating, or any other desired metal deposition technique. The thickness of oxidation prevention or wetting layer can be less than the thickness of the plated stiffener layer. For example, the thickness of the oxidation prevention or wetting layer thickness can be approximately 3 μm or less, or 1 μm or less, or 0.5 μm or less.

Metallic structure 108 can counter module warpage at room temperature. For example, the temperatures associated with bonding module 102 to substrate 136 can be associated with causing a frown shape in substrate 136 after bonding, as the CTE of substrate 136 is greater than the CTE of module 102 and in particular, greater than the CTE of electronic components 110-118. The difference in CTEs can lead to warpage of substrate 136 (e.g., frowning) as the substrate with module 102 bonded thereto cools to room temperature. Adding metallic structure 108 can counter this warpage. For example, higher plating temperatures and thicker Cu can provide increased warpage resistance during cooldown to room temperature or during other temperature changes.

In some examples, metallic structure 108 can be coupled directly to semiconductor material of electronic components 110, 112, 114, 116, and/or or 118. The material used for metallic structure 108 is selected based on CTE properties similar to those of substrate 136. For example, the difference between the overall CTE of metallic structure 108 and the overall CTE of substrate 136 can be less than the difference between the overall CTE of metallic structure 108 and the CTE of electronic component 110. For example, the overall CTE of metallic structure 108 can be within approximately 5%, approximately 10%, approximately 15%, approximately 20%, or approximately 25% of the overall CTE of substrate 136. The materials, shape, location, and/or thickness of metallic structure 108 can also be selected based on thermal conductivity in electronic device 100 and to provide benefit of heat dissipation.

Referring now to FIG. 3D, example electronic device 100 is shown at a later stage of manufacture. In the example of FIG. 3D, TIM 106 can be provided over metallic structure 108. Lid 109 can be provided over TIM 106.

TIM 106 can be disposed over metallic structure 108 and can substantially cover metallic structure 108. TIM 106 can comprise a metallic or conductive TIM. TIM 106 can include a flowable material or solder in some examples. The solidification temperatures and other properties of TIM 106 can be controlled by using different In-Ag alloys to help control overall package warpage. Reduced module warpage can enable thinner lids 109 in some examples. In some examples, a thin lid 109 can comprise a thickness of approximately 0.8 mm to approximately 1.2 mm. As used herein with numeric values, the term approximately can mean +/−5%, +/−10%, +/−15%, +/−20%, or +/−25%. Reduced module warpage can also enable thinner substrate core thicknesses of substrate 136 in some examples. For example, a thickness of the core of substrate 136 can be 800 μm or less. For example, a thickness of the core of substrate 136 can be between 400 μm and 800 μm.

Various examples can use an indium-based TIM 106. Indium can comprise Sn—Ag solder. In some examples, TIM 106 can comprise In10Ag (10% Ag), In7Ag, In5Ag, In3Ag, or pure Indium. TIM 106 can comprise other low-melting point metals such as, for example, gallium or gallium alloys. In some examples, organic TIM can be used if the organic TIM has suitable thermal conductivity. For example, an organic TIM could be loaded with ceramic particles, or a gallium TIM could be used in a polymer matrix. TIM 106 can be disposed between the upper side of metallic structure 108 and a lower side of lid 109 (e.g., comprising an inter-metallic compound (IMC) such as Ni—In). In some examples, other In alloys (e.g., In—Ag) alloys can be used to achieve different solidification temperatures and to control overall package warpage.

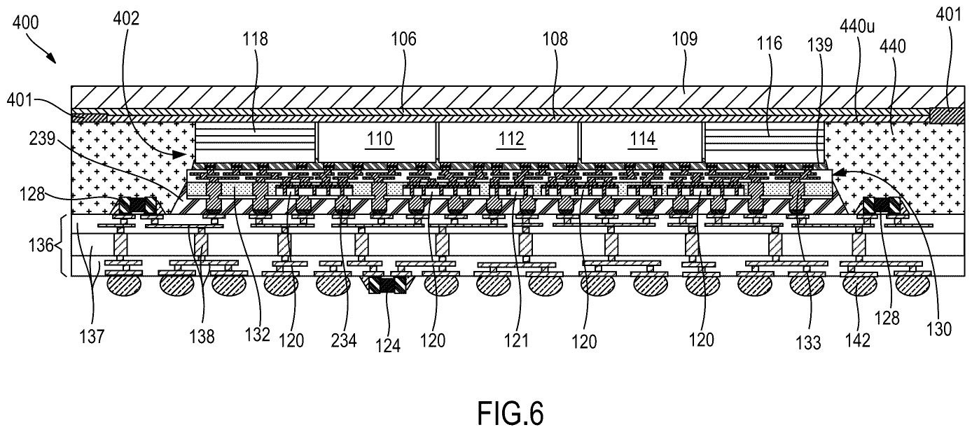

In accordance with various examples, lid 109 can comprise a square or rectangular geometry as viewed from above. In some examples, lid 109 can have trenches, protrusions, or fins on the upper side thereof to improve heat dissipation efficiency. Lid 109 can be in contact with TIM 106 and, in some examples, with a lid adhesive (as shown in electronic device 400 in FIG. 6).

In some examples, lid 109 can comprise or be referred to as a metal lid. For example, lid 109 can comprise a metal or alloy (e.g., aluminum, nickel, copper, or alloys or combinations thereof). In some examples, lid 109 can be referred to as or comprise a heat sink, heat dissipation plate, cap, cover, or body. Lid 109 can protect electronic components 110-118 from external elements. Lid 109 can promote quick dissipation of heat generated from electronic components 110-118. In some examples, the thickness of lid 109 can range from approximately 0.5 mm to approximately 5.0 mm, approximately 0.8 mm to approximately 1.2 mm or approximately 2.0 mm to approximately 4.0 mm.

After lid 109 is seated on TIM 106, TIM 106 can be cured through a curing process using heat, light, ultraviolet rays, laser, or any other suitable curing treatment. TIM 106 can be cured to reduce fluidity through a heat treatment in some examples. Lid 109 can be coupled to metallic structure 108 through TIM 106. In some examples, the lateral sides of lid 109 can be coplanar with the lateral sides of encapsulant 140 and metallic structure 108.

FIG. 3E shows electronic device 100 at a later stage of manufacture. In the example shown in FIG. 3E, external interconnects 142 can be provided. In some examples, one or more lower electronic component(s) 124 can also be provided between adjacent external interconnects 142. External electronic component 124 can comprise an IPD or active component.

In some examples, external interconnects 142 can comprise or be referred to as solder, solder balls, bumps, tin bumps, tin-lead (SnPb) bumps, lead-free bumps, pads, pillars, etc. External interconnects 142 can be coupled to outer terminals 138b of substrate 136. External interconnects 142 can serve to couple electronic device 100 to an external device.

External interconnects 142 can be coupled to and in contact with outward terminals of substrate 136. In some examples, external interconnects 142 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 142 can be provided by forming a conductive material including solder on outer terminals 138b of substrate 136 through a ball drop method, and then a reflow process. External interconnects 142 can comprise or be referred to as conductive balls such as solder balls, conductive pillars such as copper pillars, conductive posts, bumps, or solder capped copper pillars. In some examples, the height of external interconnects 142 can range from about 25 μm to about 100 μm. In some examples, external interconnects 142 can be referred to as external input/output terminals of electronic device 100. In some examples, electronic device 100 can comprise a land grid array (LGA) and outer terminals 138b of substrate 136 serve as external input/output terminals of electronic device 100. For example, electronic device 100 can be devoid of external interconnects 142 leaving terminals of substrate 136 exposed for interconnection.

In some examples (e.g., when substate 136 is part of a strip, wafer, or panel of substrates 136) singulation can also be performed. In accordance with various examples, singulation can be performed by cutting through saw streets, for example disposed around a perimeter of electronic devices 100, thereby separating individual electronic devices 100 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through encapsulant 140, substrate 136, TIM 106, metallic structure 108, and/or lid 109. In some examples, after singulation, encapsulant 140 can be coplanar with the substrate 136, TIM 106, metallic structure 108, and lid 109.

In various examples, metallic structure 108 can counter room-temp module warpage, which can result in a cry shape. Metallic structure 108 can comprise plating of metals or metal alloys at to counter module warpage at room temp. Higher plating temperatures and greater thicknesses of metallic structure 108 can increase warpage resistance during temperature changes such as, for example, during cool down to room temperature.

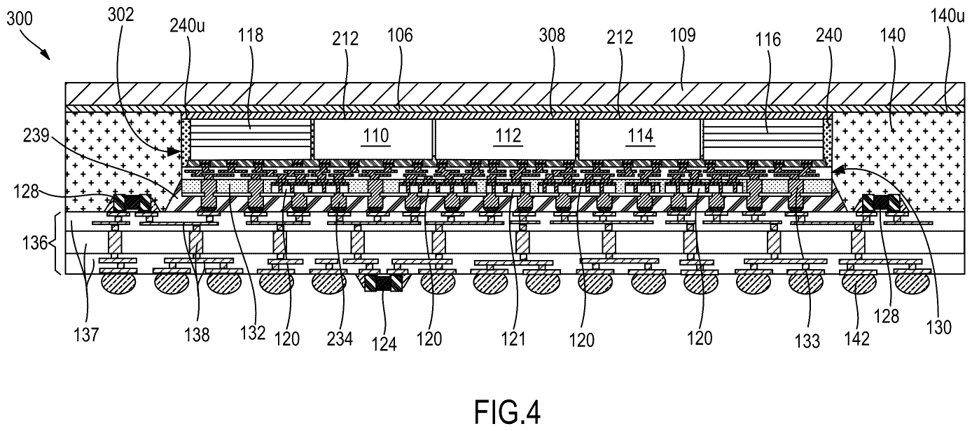

Referring now to FIG. 4, an example electronic device 300 is shown according to various embodiments. Various components of electronic device 300 can be similar to or the same as those of electronic device 100 (of FIGS. 1, 2A-2J, and 3A-3E) or other electronic devices described herein. Electronic device 300 can comprise module 302. Module 302 can be similar to module 102, but can include metallic structure 308.

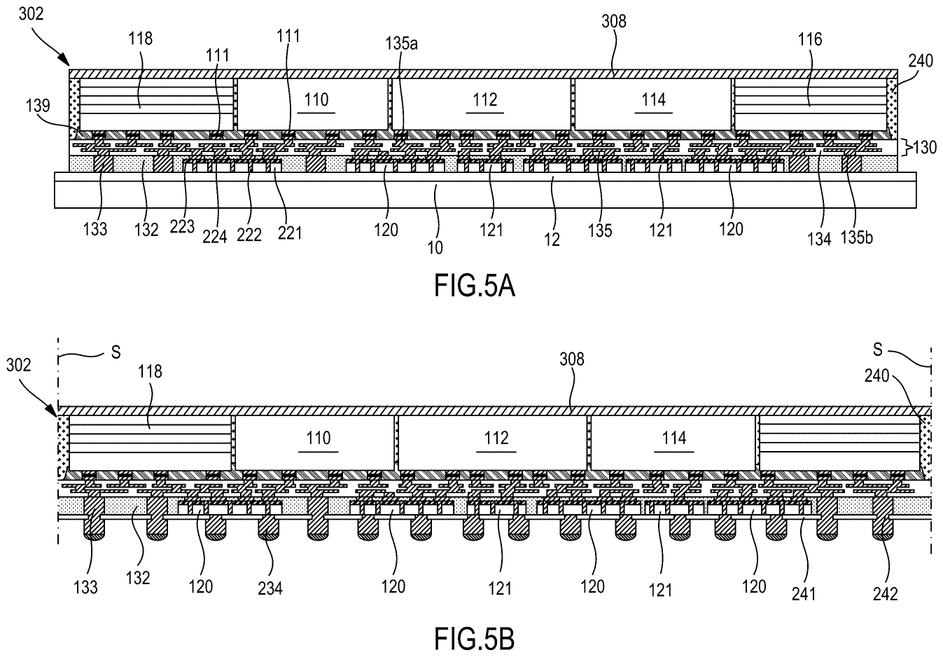

With momentary reference to FIGS. 5A-5B, an example method of making module 302 of electronic device 300 using cross-sectional views, is shown. In FIG. 5A, module 302 is shown after having been manufactured using the steps shown in FIG. 2A through 2H. In this regard, FIG. 5A can be performed after the steps shown in FIGS. 2A-2H. In FIG. 5A, metallic structure 308 is provided over encapsulant 240 and electronic components 110-118. The elements, features, materials, or manufacturing methods of metallic structure 308 can be similar to or the same as those of metallic structure 108, as previously described.

With reference to FIG. 5B, module 302 is shown at a later stage of manufacture. In the example shown in FIG. 5B, lower passivation 241, lower conductive structure 242, and module interconnects 234 can be provided, as previously described. In the example shown in FIG. 5B, singulation can also be performed. In some examples, singulation can be performed by cutting through saw streets, for example indicated by lines S, disposed around a perimeter of modules 302, thereby separating individual modules 302 from one another. Singulation can include cutting through metallic structure 308, encapsulant 240, redistribution structure 130, encapsulant 132, and/or lower passivation 241. After singulation metallic structure 308, encapsulant 240, redistribution structure 130, encapsulant 132, and/or lower passivation 241 can be coplanar with one another.

Returning to FIG. 4, manufacture of electronic device 300 can be similar to manufacture of electronic device 100, as shown in FIGS. 3A-3E, but using module 302 in place of module 102. During deposition of encapsulant 140, encapsulation techniques (e.g., film assist molding or mold chase design) can be used to prevent or block encapsulant 140 from extending over metallic structure 308. In some examples, encapsulant 140 can be over metallic structure, initially, but can then be removed from over metallic structure 308 (e.g., using grinding or etching). In accordance with various examples, encapsulant 140 can disposed around the lateral sides of module 302 and thus the lateral sides of metallic structure 308. In some examples, TIM 106 can be on and/or can contact the upper side 140u of encapsulant 140.

In various examples, metallic structure 308 can counter room-temp module warpage, which can result in a cry shape. Metallic structure 308 can comprise plating of metals or metal alloys at the wafer level to counter module warpage at room temp. Metallic structure 308 can reduce warpage of module 302, as the CTE of metallic structure 308 can compensate for or counterbalance the difference in the CTE of redistribution structure 130 and the CTE of electronic components 110-118. In some examples, the overall CTE of metallic structure 308 can be within approximately 5%, approximately 10%, approximately 15%, approximately 20%, or approximately 25% of the overall CTE of redistribution structure 130.

Reducing warpage of module 302 can provide more reliable bonding between module 102 and substrate 136. Metallic structure 308 can also reduce warpage of substrate 136, as the CTE of metallic structure 308 can compensate for or counterbalance the difference in CTE of substrate 136 and the CTE of electronic components 110-118. In some examples, the overall CTE of metallic structure 308 can be within approximately 5%, approximately 10%, approximately 15%, approximately 20%, or approximately 25% of the overall CTE of substrate 136. Higher plating temperatures and greater thicknesses of metallic structure 308 can increase warpage resistance during temperature changes such as, for example, during cool down to room temperature.

With reference to FIG. 6, an example electronic device 400 is shown, in accordance with various embodiments. Elements, features, materials, or manufacturing methods of electronic device 400 can be similar to or the same as those of electronic device 100 (of FIG. 1) or other electronic devices described herein. Module 402 can be similar to module 102, though module 402 can omit encapsulant 240.

In various examples, electronic device 400 can comprise encapsulant 440 disposed around the lateral sides of module 402. Encapsulant 440 can be coupled and/or can contact the sidewalls of electronic components 110-118 and/or underfill 139. Encapsulant 440 can be coupled to the sidewalls redistribution structure 130, encapsulant 132, or underfill 239. Encapsulant 440 can be coupled to passive devices 128 and 129 in some examples. The back sides of electronic components 110-118 can be substantially coplanar with the outer side 440u of encapsulant 440.

In some examples, a lid adhesive 401 can be provided between lid 109 and encapsulant 440. In some examples, lid adhesive 401 can contact lid 109 and encapsulant 440. In some examples, lid adhesive 401 can contact encapsulant 440 and TIM 106.

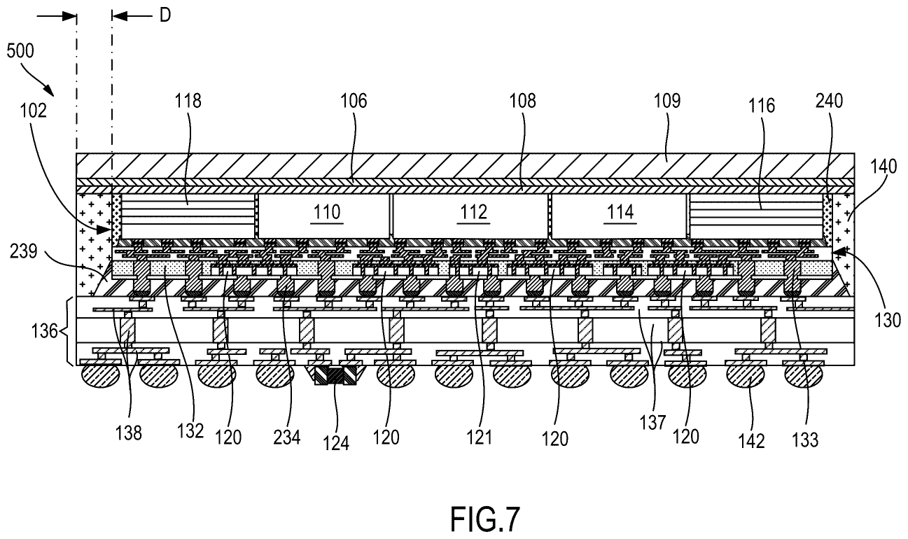

Referring now to FIG. 7, an example electronic device 500 is shown in accordance with various examples. Elements, features, materials, or manufacturing methods of electronic device 500 can be similar to or the same as those of electronic device 100 (of FIG. 1) or electronic device 300 (of FIG. 4), or other electronic devices described herein. In the example of FIG. 7, module 102 can comprise an area (or “footprint”) substantially similar to a footprint of substrate 136. For example, the distance D between the lateral side of module 102 and the lateral side of substrate 136 can be less than less than 1.0 mm, less than 0.5 mm, or less than 0.1 mm. IPDs 128 can be omitted from the upper side of substrate 136. In various examples, IPDs can be disposed on the lower side of substrate 136 or embedded in the substrate or the interposer (e.g., embedded in mold material 132 of module 102).

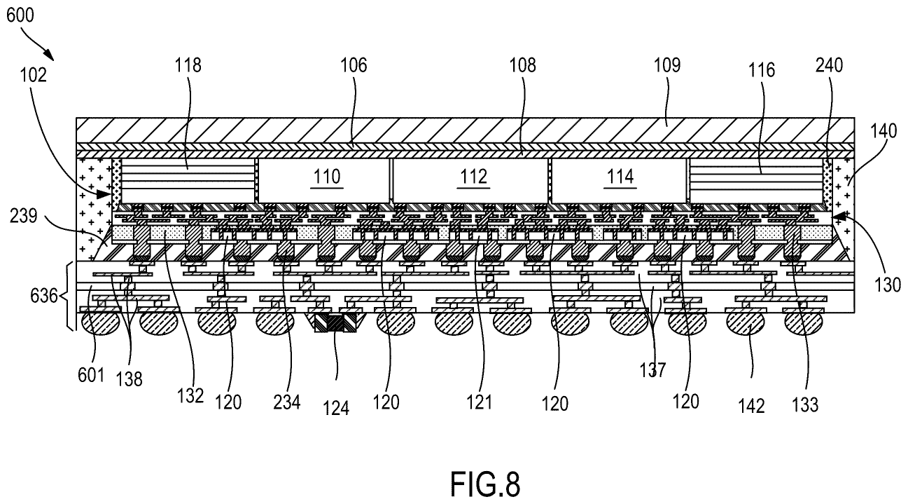

Referring now to FIG. 8, an example electronic device 600 is shown in accordance with various examples. Elements, features, materials, or manufacturing methods of electronic device 600 can be similar to or the same as those of electronic device 500 (of FIG. 7) or of other electronic devices described herein. In some examples, substrate 636 can comprise a thin core 601 (e.g., a core thickness of less than 1.24 mm). For example, substrate 636 can comprise a core thickness in a range of approximately 0.4 mm to approximately 0.8 mm, approximately 0.5 mm to approximately 1.20 mm, approximately 0.5 mm to approximately 1.0 mm, or of approximately 0.8 mm. In some examples, substrate 636 can be coreless. In some examples, substrate 636 can have a footprint in the range of approximately 5 mm×5 mm to approximately 110 mm×110 mm.

Metallic structure 108 and/or flat lid 109, the substrate core 601 can be thinner than in other configurations. The thin core 601 of substrate 636 can comprise thru-core vias closer together (than thicker core substrates), which can have a positive effect in differential pair impedance.

In various examples, reverse-lab thermocompression (RLTC) can be used to form electronic device 600. U.S. Pat. No. 11,749,637 describes RLTC in greater detail and is incorporated herein by reference for any purpose. A low temperature heating can be applied to join module interconnects 234 to substrate 636. Coupling module 102 to substrate 636 at normal mass reflow (e.g., isothermal) temperatures can cause module 102 and substrate 636 to form a mechanically bonded unit that is both strong (e.g., has a high modulus) and is prone to crying as the CTE of substrate 636 is higher than the CTE of module 102. In some examples, when both the module 102 and substrate 636 cool at the same time (isothermally), the substrate 636 can shrink more than the module 102. Uneven shrinkage or expansion can create a cry shape. Metallic structure 108 can increase the CTE of module 102 to limit uneven shrinkage.

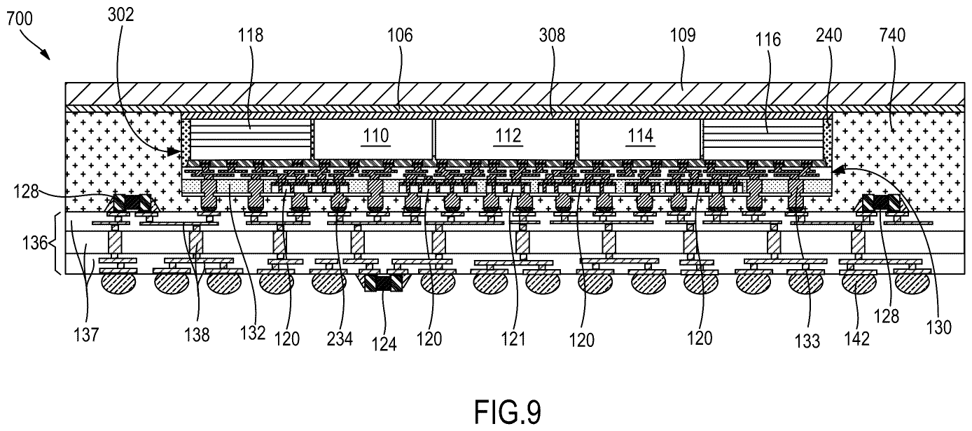

Referring now to FIG. 9, example electronic device 700 is shown, in accordance with various embodiments. Elements, features, materials, or manufacturing methods of electronic device 700 can be similar to or the same as those of electronic device 300 (of FIG. 4), electronic device 100 (of FIG. 1), or other electronic devices described herein. Encapsulant 740 of electronic device 700 can be used to underfill module 302. Underfill 239 (of FIG. 1) can be omitted. The CTE of encapsulant 740 can be lower than the CTE of underfill 239 (of FIG. 1) and can simplify the stress profiles in the electronic device 700. Encapsulant 740 can be coupled to the upper side of substrate 136 between substrate 136 and module 102. Encapsulant 740 can surround and/or contact module interconnects 234.

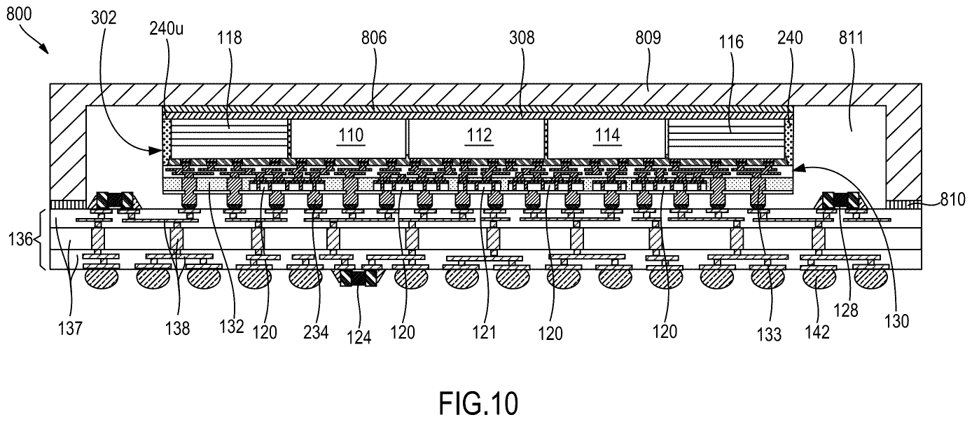

FIG. 10 shows a cross-sectional view of an example electronic device 800. Elements, features, materials, or manufacturing methods of electronic device 800 can be similar to or the same as those of electronic device 300 (of FIG. 4), electronic device 100 (of FIG. 1) or other electronic devices described herein.

In the example shown in FIG. 10, electronic device 800 comprises module 302 including encapsulant 240 disposed around and substantially coplanar with electronic components 110, 112, 114, 116, 118. Metallic structure 308 can be coupled to upper side 240u of encapsulant 240 and to the upper sides of each of electronic components 110-118. TIM 806 can be over metallic structure 308. TIM 806 can be disposed between metallic structure 308 and the inner side of lid 809. Lid 809 can comprise legs or sidewalls extending around the lateral sides of module 302 to substrate 136. Lid 809 can be coupled to substrate 136 by lid adhesive 810, in some examples. Lid adhesive 810 can be coupled to an inner side of substrate 136 and to a lower side of the leg or sidewall of lid 809. Module 302 can be enclosed in volume 811 defined between lid 809 and substrate 136. IPDs 128 can be coupled to substrate 136 and devoid of mold material. Metallic structure 308 can reduce warpage of module 302, as the CTE of metallic structure 308 can compensate for or counterbalance the difference in the CTE of redistribution structure 130 and the CTE OF electronic components 110-118. Reducing warpage of module 302 can provide more reliable bonding between module 102 and substrate 136. Metallic structure 308 can also reduce warpage of substrate 136, as the CTE of metallic structure 308 can compensate for or counterbalance the difference in the CTE of substrate 136 and the CTE of electronic components 110-118.

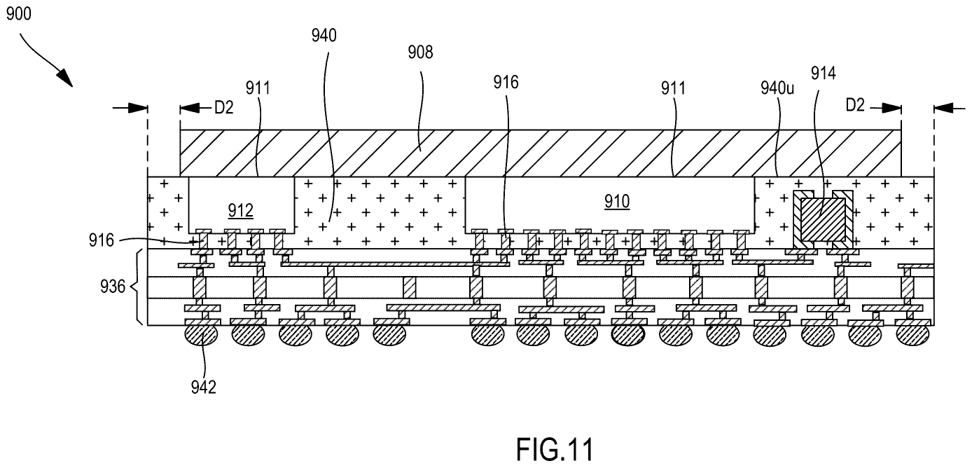

FIG. 11 shows a cross-sectional view of an example electronic device 900. Elements, features, materials, or manufacturing methods of electronic device 900 can be similar to or the same as those of the electronic devices depicted in FIGS. 1-10 and described above. In the example of FIG. 11, electronic device 900 comprises electronic component 910, electronic component 912, electronic component 914, substrate 936, encapsulant 940, metallic structure 908, and external interconnects 942. Metallic structure 908 can be coupled to encapsulant 940 and to backsides of 911 of electronic components 910 and 912 exposed from encapsulant 940. The sidewall of metallic structure 908 can be inset from the sidewall of encapsulant 940 by a pullback distance D2. Electronic components 910 and 912 can each be coupled to substrate 936 via component interconnects 916 of each of electronic component 910, 912. Component interconnects 916, which can be similar to component interconnects 111, as previously described, can be bonded with their respective upper terminals of substrate 936 through a reflow process, a thermal compression process, a hybrid bonding process, or a laser assisted bonding process.

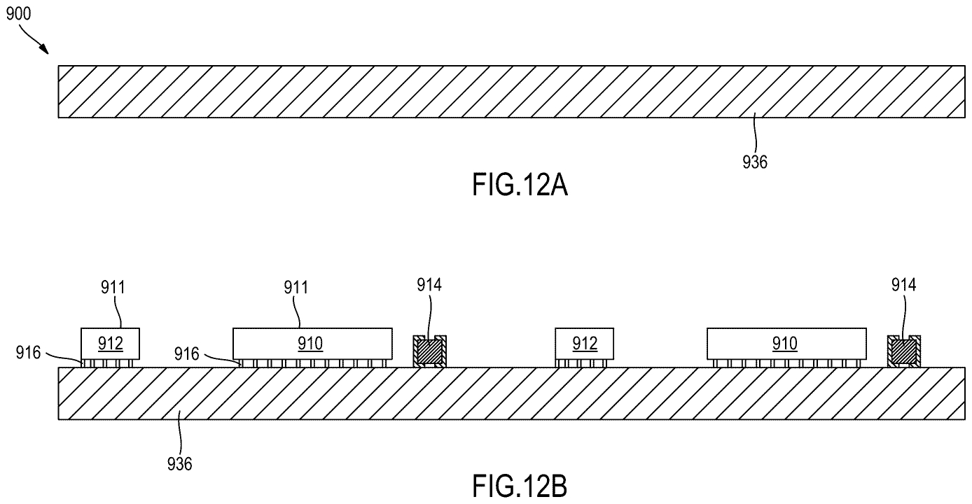

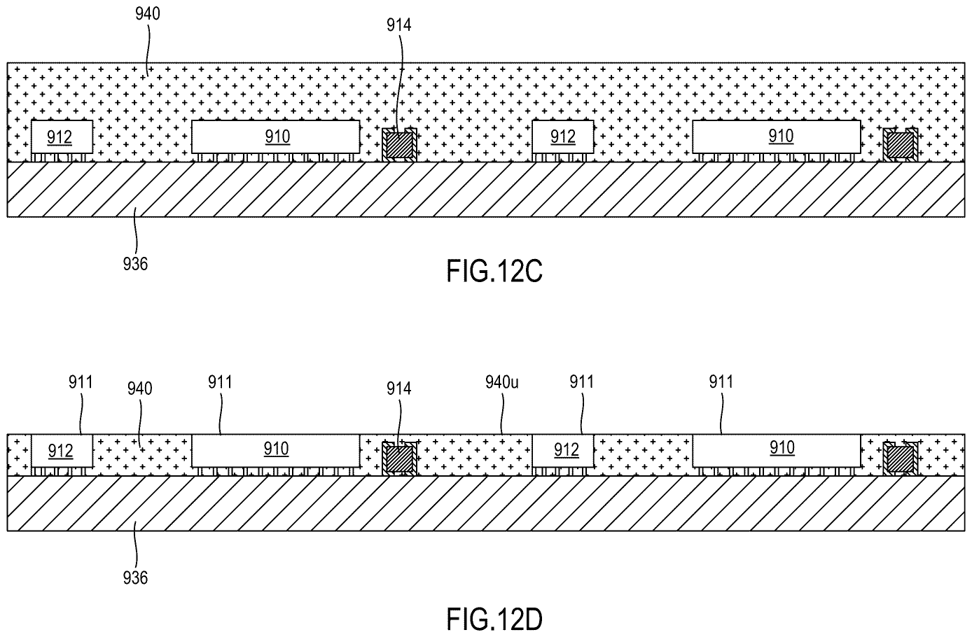

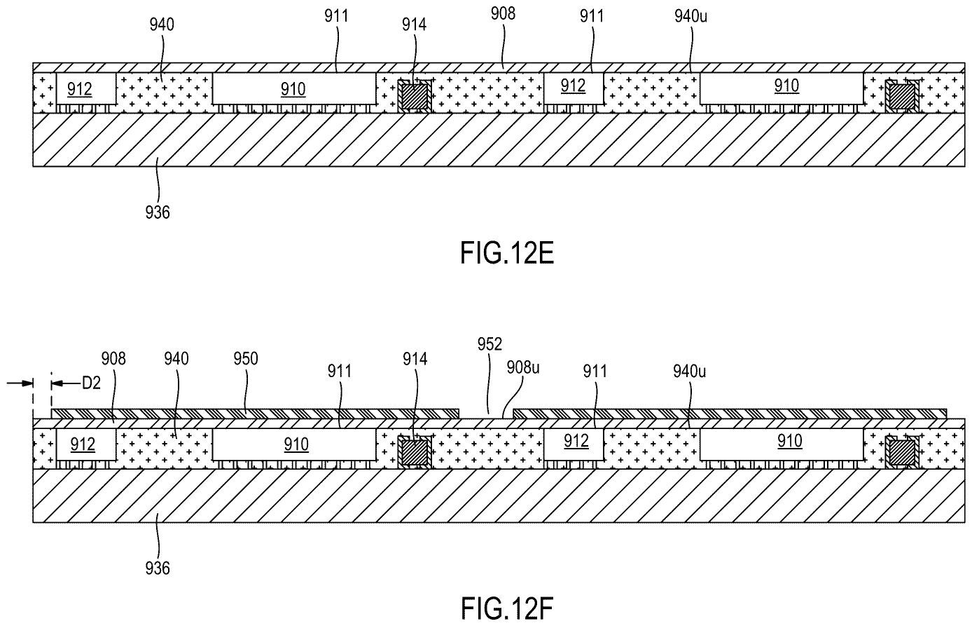

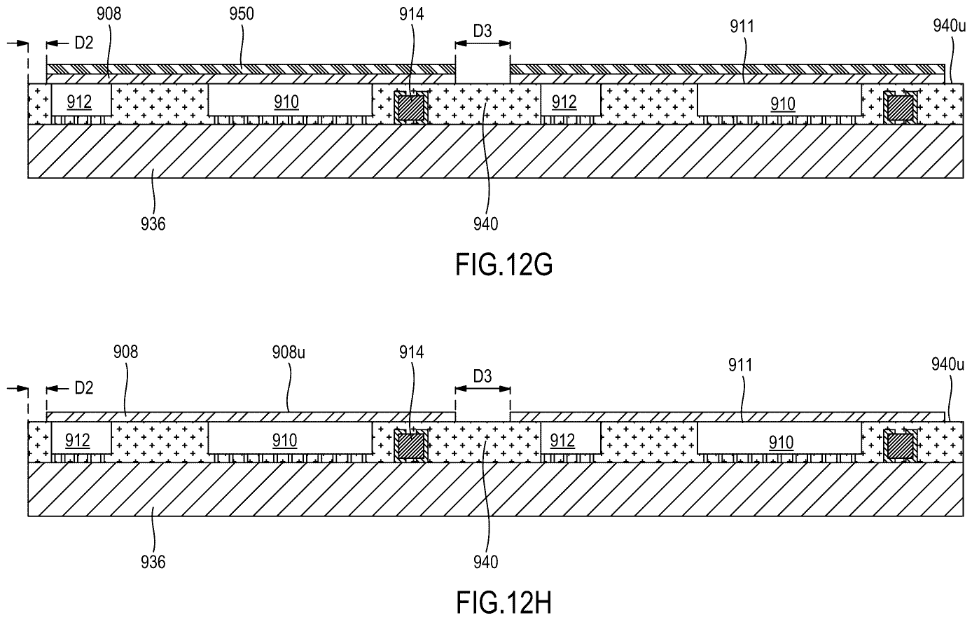

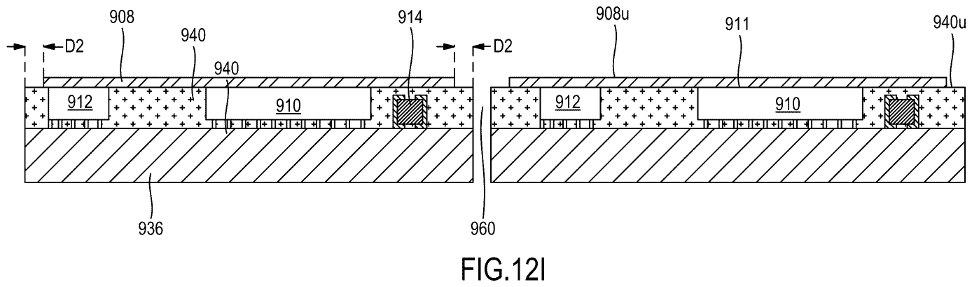

FIGS. 12A through 12I show an example method of making electronic device 900, in accordance with various examples. FIG. 12A shows electronic device 900 at an early stage of manufacture. In the example of FIG. 12A, substrate 936 can be provided. Elements, features, materials, or manufacturing methods of substrate 936 can be similar to or the same as those of substrate 136 or other substrates described herein.

FIG. 12B shows electronic device 900 at a later stage of manufacture and in accordance with various examples. In the example of FIG. 10B, electronic components 910, 912, and 914 can be coupled to substrate 936. Elements, features, materials, or manufacturing methods of electronic components 910, 912, and 914 can be similar to or the same as electronic components 110-118 of electronic device 100 or other electronic components described herein. In accordance with various examples, electronic components 910 and 912 can each comprise or be referred to as a die, chip, semiconductor package (e.g., multiple interconnected and/or stacked die and/or one or more die coupled to an interposer substrate), passive component, antenna patch, or power device. In some examples, one or more of electronic components 910, 912 can comprise a digital signal processor (DSP), network processor, power management unit, audio processor, radio-frequency (RF) circuit, wireless baseband processor, system-on-chip (SoC) processor, sensor, or application-specific integrated circuit (ASIC). In some examples, electronic component 910 and electronic component 912 can each comprise a different type of die or package. For example, one of electronic component 910 and electronic component 912 can comprise memory die, memory package(s), or power device (e.g., high voltage (HV) or low voltage (LV) die) and the other of electronic component 910 and electronic component 912 can comprise a logic die or other type semiconductor package. In some examples, electronic component 914 can be a passive component (e.g. capacitor, resistor, inductor, etc.).

FIG. 12C shows electronic device 900 at a later stage of manufacture and in accordance with various examples. In the example of FIG. 12C, encapsulant 940 can be provided over electronic components 910, 912, and 914. Elements, features, materials, or manufacturing methods of encapsulant 940 can be similar to or the same as those of encapsulant 140 of FIG. 1 or other encapsulants or mold materials described herein. Encapsulant 940 can cover the back sides of electronic components 910, 912, and 914 in the example of FIG. 10C.

FIG. 12D shows electronic device 900 at a later stage of manufacture and in accordance with various examples. In the example of FIG. 12D, a portion of encapsulant 940 can be removed to expose back sides 911 of electronic components 910 and 912. In some examples, a back-grinding process can be performed to remove encapsulant 940 from over electronic components 910 and 912. After back-grinding, upper side 940u of encapsulant 940 can be substantially coplanar with back sides 911 of electronic components 910 and 912.

FIG. 12E shows electronic device 900 at a later stage of manufacture and in accordance with various examples. In the example of FIG. 12E, metallic structure 908 can be provided. Elements, features, materials, or manufacturing methods of metallic structure 908 can be similar to or the same as those of metallic structure 108 of FIG. 1 or other metallic structures described herein. In some examples, metallic structure 908 can comprise an inner or adhesion layer (e.g., a layer of Ti, TiW, or SuS) and an outer or stiffener layer (e.g., a layer of Cu). In some examples, the inner layer can be provided by sputtering and the outer layer can be provided by plating over the inner layer. Metallic structure 908 can be formed over encapsulant 940 and over electronic components 910 and 912. In some examples, the thickness of the outer layer is greater than the thickness of the inner layer. For example, the plated layer can have thickness greater than 3.0 μm, greater than 5.0 μm, or greater than 10 μm, and the inner layer can have thickness less than 3.0 μm, less than 1.0 μm, or less than 0.5 μm. In some examples, metallic structure 908 can be coupled directly to outer side 940u of encapsulant 940 and the back sides 911 of electronic components 910 and 912. Metallic structure 908 can, initially, completely cover outer side 940u of encapsulant 940 and back sides 911 of electronic components 910 and 912 as depicted in the example of FIG. 12E.

FIG. 12F shows electronic device 900 at a later stage of manufacture and in accordance with various examples. In the example of FIG. 12F, mask 950 can be provided over metallic structure 908. Mask 950 can comprise photoresist, in some examples.

In accordance with various examples, mask 950 can define openings 952 that expose an outer side 908u of metallic structure 908. Mask 950 can be a patterned mask (or template) that covers areas of metallic structure 908 and leaves other areas of metallic structure 908 exposed through openings 952. Opening 952 can have a width greater than or equal to distance D2. Distance D2 can be less than approximately 1.0 mm in some examples. In some examples, distance D2 can be approximately 0.1 mm, approximately 0.2 mm, approximately 0.3 mm, approximately 0.4 mm, or approximately 0.5 mm. In some examples, openings 952 can comprise a width D3 (FIG. 12G) of twice distance D2 plus a width of the saw street between adjacent electronic devices 900. In some examples, the thickness of mask 950 can range from approximately 1 μm to approximately 1000 μm.

FIG. 12G shows electronic device 900 at a later stage of manufacture and in accordance with various examples. In the example of FIG. 12G, a portion of metallic structure 908 exposed from mask 950 can be removed. In various examples, the portions of metallic structure 908 exposed from mask 950 can be removed by chemical (wet or dry) etching or electrochemical etching. Wet etching can dissolve metallic structure 908 using a specific chemical solution, while dry etching can precisely remove exposed metallic structure 908 using plasma.

FIG. 12H shows electronic device 900 at a later stage of manufacture and in accordance with various examples. In the example of FIG. 12H, mask 950 can be removed. Mask 950 can be removed or stripped, leaving outer side 908u of metallic structure 908 exposed.

FIG. 12I shows electronic device 900 at a later stage of manufacture and in accordance with various examples. In the example of FIG. 12I, electronic devices 900 can be singulated. In accordance with various examples, singulation can be performed by cutting through saw streets 960 thereby separating individual electronic devices 900 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through encapsulant 940 and substrate 936.

In some examples, after singulation, encapsulant 940 can be substantially coplanar with the substrate 936. Metallic structure 908 can be inset or staggered inward from the sidewalls of encapsulant 940. In some examples, metallic structure 908 can be inset by distance D2 from the sidewalls of encapsulant 940. Distance D2 can be less than 1.0 mm or less than 0.5 mm. For example, D2 can be approximately 0.5 mm, approximately 0.4 mm, approximately 0.3 mm, or between approximately 0.1 mm and 0.2 mm, in various examples.

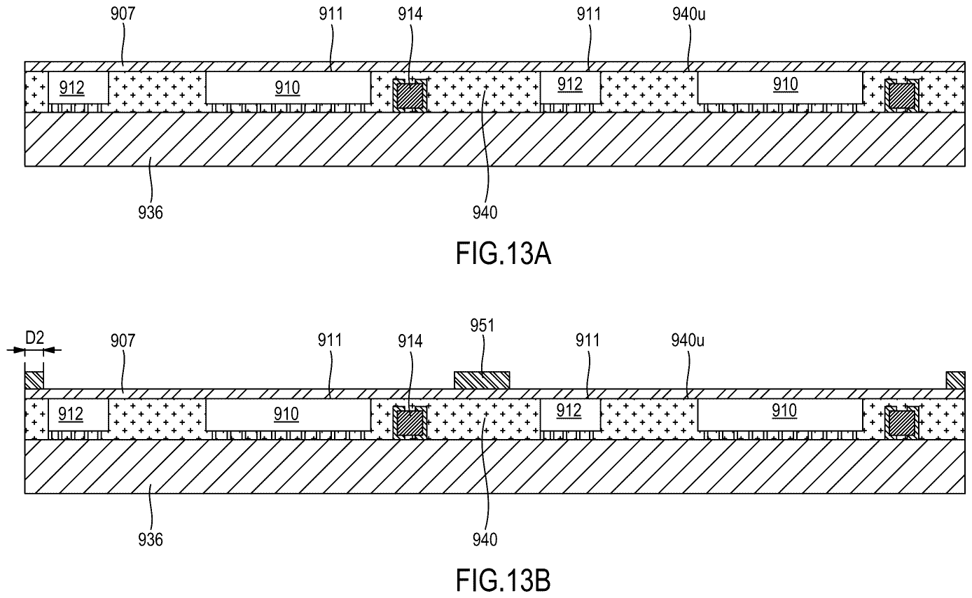

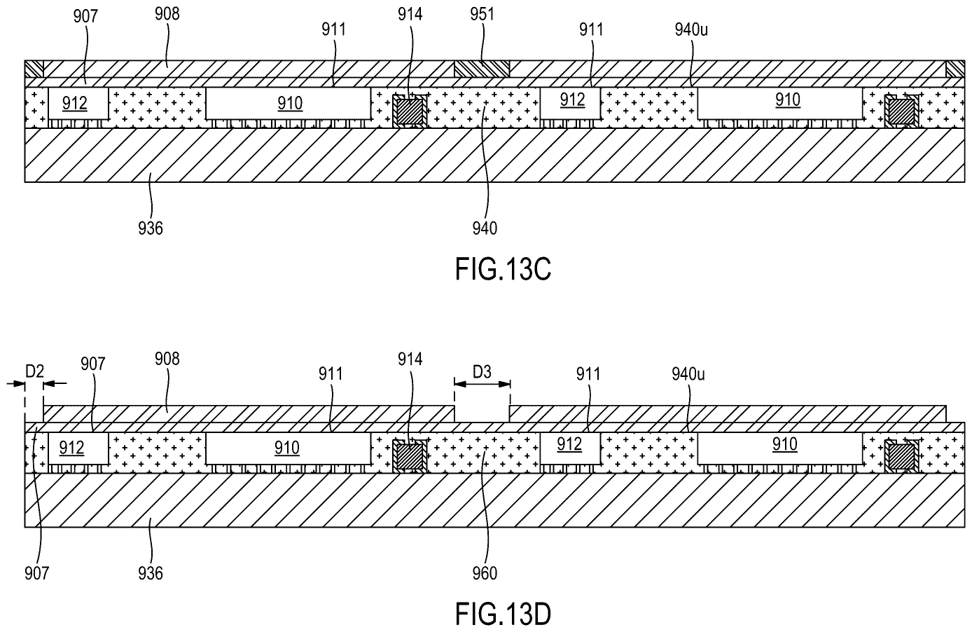

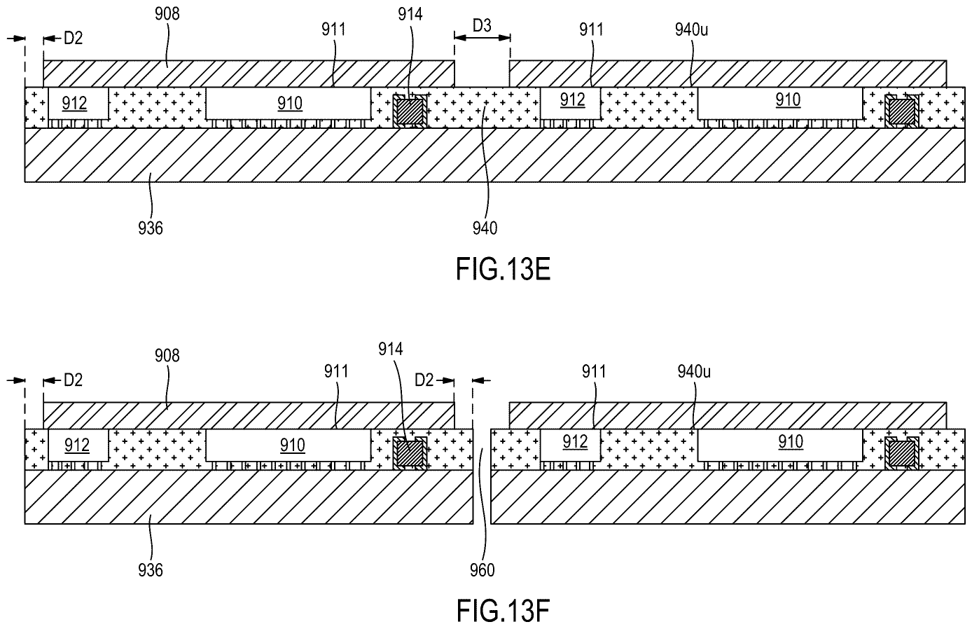

Referring now to FIGS. 13A through 13F, an example method for making electronic device 900 is shown, in accordance with various embodiments. FIG. 13A shows electronic device 100 during a manufacturing process continuing from removal of a portion of encapsulant 940 as shown in FIG. 12D. In the example of FIG. 13A, seed 907 can be provided.

In various examples, seed 907 can be provided over the exposed side of electronic components 910, 912 and over the outer side 940u of encapsulant 940. In some examples, seed 907 can comprise Ti, TiW, Cu, Au, or other metals or alloys. The seed layer can be provided by sputtering, PVD, CVD, MOCVD, ALD, LPCVD, or PECVD. The thickness of the seed layer can range from approximately 1 nanometer (nm) to approximately 10 nm. The seed layer can provide a path for the flow of current in examples including a conductor that is electroplated at a later stage of manufacture.

FIG. 13B shows electronic device 900 at a later stage of manufacture and in accordance with various examples. In the example of FIG. 13B, mask 951 can be provided. Elements, features, materials, or manufacturing methods of mask 951 can be similar to or the same as those described above for mask 950. Mask 951 can comprise photoresist or other insulating material suitable for masking portions of seed 907 for later plating. Mask 951 can be selectively placed over seed 907 in some examples. Photoresist can be provided completely covering seed 907 and then selectively removed to leave mask 951 patterned over seed 907 in some examples.

In various examples, mask 951 can have a width that is greater than or equal to distance D2, as described above. Portions of mask 951 over saw street or over adjacent electronic devices 900 can have a width D3 approximately twice D2 plus the width of the saw street. In that regard, mask 951 can be configured with a width suitable to leave a later-formed conductor with an inset distance of approximately D2.

FIG. 13C shows electronic device 900 at a later stage of manufacture and in accordance with various examples. In the example of FIG. 13C, metallic structure 908 can be provided.

In some examples, a conductor can be plated on seed 907 to form metallic structure 908. In some examples, the conductor can be formed over portions of seed 907 exposed from mask 951. Metallic structure 908 can be patterned into openings defined by mask 951. The conductor plated to form conductive structure can comprise Cu, Al, Ni, Au, Ag, Pt, or any other suitable conductive material. The thickness of the plated conductor can be between 3.0 μm and 35 μm, in some examples. For example, the thickness of the plated conductor can be greater than 3.0 μm, greater than 5.0 μm, or greater than 10.0 μm in some examples. Metallic structure 908 can include seed 907 and the conductor plated onto seed 907. In some examples, metallic structure 908 can be provided by using other metal deposition techniques such as, for example, sputtering, PVD, CVD, MOCVD, ALD, LPCVD, PECVD, or any other suitable deposition.

FIG. 13D shows electronic device 900 at a later stage of manufacture and in accordance with various examples. In the example of FIG. 13D, mask 951 can be stripped or removed. Metallic structure 908 can define a step structure with a width or inset distance D2 from the edge of electronic device 900. Seed 907 can remain in step structures or gaps defined by metallic structure 908.

FIG. 13E shows electronic device 900 at a later stage of manufacture and in accordance with various examples. In the example of FIG. 13E, a portion of seed 907 exposed from the conductor deposited to form metallic structure 908 can be removed. In some examples, a wet or dry etching process can be performed to remove exposed portions of seed 907. A flash etch can be performed to remove exposed portions of seed 907 in some examples. Removal of exposed portions of seed 907 can leave adjacent metallic structures 908 electrically isolated from one another. Removal of exposed portions of seed 907 can expose upper side 940u of encapsulant 940.

FIG. 13F shows electronic device 900 at a later stage of manufacture and in accordance with various examples. In the example of FIG. 13F, electronic devices 900 can be singulated. Singulation can be performed using structures and techniques similar to or the same as those of FIG. 12I or otherwise described herein.

In various examples, electronic devices and related manufacturing techniques can improve warpage performance using backside metallization applied over electronic components and encapsulation. Some examples can reduce manufacturing costs by avoiding the cost of discretely stamping and attaching heat spreaders. Thermal performance can be improved by reducing or eliminating the impact of thermal interface material along the bond line, which can avoid void formation in the TIM and eliminate costs associated with applying TIM. Heat spreaders, such as metallic structure 908, formed directly on electronic devices can also have reduced pullback or inset from package edge. Reduced pullback can result in increased coverage of the package by the heat spreader and can accordingly improve thermal performance. For example, a forming (e.g., plating) the heat spreader directly on the package can result in a greater surface area percentage of the package being covered by the heat spreader, as compared to the percentage of the package surface area covered by a preformed heat spreader that is subsequently coupled to the package.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a module including electronic components and a first encapsulant disposed around lateral sides of the electronic components;
a substrate coupled to the module;
a metallic structure coupled to a side of the module opposite the substrate, the metallic structure coupled to back sides of the electronic components;
a thermal interface material coupled to the metallic structure; and
a lid coupled to the thermal interface material.

2. The electronic device of claim 1, wherein the module comprises:
a module substrate coupled to the electronic components and to the substrate; and
a dummy die embedded in the module substrate.

3. The electronic device of claim 1, wherein the module comprises:
a module substrate coupled to the electronic components and to the substrate; and
a bridge die embedded in the module substrate.

4. The electronic device of claim 1, wherein the module comprises:
a module substrate coupled to the electronic components and to the substrate; and
a passive device embedded in the module substrate.

5. The electronic device of claim 1, further comprising a second encapsulant coupled to the substrate and a lateral side of the module.

6. The electronic device of claim 5, wherein a lateral side of the metallic structure is coupled to an inner side of the second encapsulant.

7. The electronic device of claim 5, wherein the second encapsulant is coplanar with the first encapsulant and the electronic components, and wherein a sidewall of the metallic structure is coplanar with a sidewall of the second encapsulant and a sidewall of the substrate.

8. An electronic device, comprising:
a substrate;
a first electronic component coupled to the substrate;
a second electronic component coupled to the substrate adjacent the first electronic component;
an encapsulant disposed over the substrate and around lateral sides of the first electronic component and the second electronic component; and
a metallic structure coupled directly to a back side of the first electronic component, a back side of the second electronic component, and an outer side of the encapsulant, wherein the metallic structure is inset from a lateral side of the encapsulant by a pullback distance.

9. The electronic device of claim 8, wherein the back side of the first electronic component, the back side of the second electronic component, and the outer side of the encapsulant are coplanar.

10. The electronic device of claim 9, wherein the metallic structure is coupled directly to the back side of the first electronic component, the back side of the second electronic component, and the outer side of the encapsulant.

11. The electronic device of claim 8, wherein the pullback distance is less than 0.5 micrometers (μm).

12. The electronic device of claim 8, further comprising a passive device coupled to the substrate with the encapsulant disposed over the passive device.

13. The electronic device of claim 8, wherein the metallic structure comprises a seed coupled directly to the back side of the first electronic component, the back side of the second electronic component, and the outer side of the encapsulant.

14. A method of making an electronic device, comprising:
providing a module including electronic components and a first encapsulant disposed around lateral sides of the electronic components;
providing a substrate with the module coupled to an inner side of the substrate;
providing a metallic structure over the module with the metallic structure coupled to outer sides of the electronic components that are exposed from the first encapsulant;
providing a thermal interface material (TIM) over the metallic structure; and
providing a lid over the TIM.

15. The method of claim 14, wherein providing the module further comprises providing a dummy die embedded in a module substrate of the module.

16. The method of claim 14, further comprising:
providing a second encapsulant around the lateral sides of the module; and
providing the metallic structure over the second encapsulant.

17. The method of claim 14, further comprising providing external interconnects coupled to an outer side of the substrate opposite the module.

18. The method of claim 14, further comprising:
providing a lid adhesive coupled to the substrate; and
coupling a leg of the lid to the lid adhesive.

19. The method of claim 18, further comprising:
providing a passive device coupled to the substrate adjacent the module: and
providing the lid over the passive device.

20. The method of claim 14, further comprising:
providing a second encapsulant around the lateral sides of the module; and
providing the TIM over the second encapsulant.
